(19) United States
(12) Patent Application Publication
(10) Pub. No.: US 2004/0248043 A1
(43) Pub. Date: Dec. 9, 2004

(54) Exposure method, exposure apparatus and device manufacturing method

(75) Inventor: Naomasa Shiraishi, Tokyo (JP)

Correspondence Address: OLIFF & BERRIDGE, PLC, P.O. BOX 19928, ALEXANDRIA, VA, 22320, US

(73) Assignee: NIKON CORPORATION, Tokyo (JP)

(21) Appl. No.: 10/855,334

(22) Filed: May 28, 2004

Related U.S. Application Data
(60) Provisional application No. 60/486,283, filed on Jul. 11, 2003.

(30) Foreign Application Priority Data
Jun. 3, 2003 (JP) 2003-158732

(51) Int. Cl. G03F 7/00

(52) U.S. Cl. 430/311; 355/53; 430/396

(57) ABSTRACT

An exposure method and apparatus illuminates a pattern of a mask with illumination light to transfer an image of the pattern onto a substrate via a projection optical system. At least a part of the pattern on the mask has a longitudinal direction extending in a first direction. The method and apparatus set a first incident angle range in the first direction of the illumination light illuminated onto the mask to be wider than a second incident angle range in a second direction orthogonal to the first direction of the illumination light illuminated onto the mask.

### PRIOR PROVISIONAL APPLICATION

This non-provisional application claims the benefit of U.S. Provisional Application No. 60/486,283 filed Jul. 11, 2003.

### INCORPORATION BY REFERENCE

The disclosure of the following priority application is herein incorporated by reference in its entirety: Japanese Patent Application No. 2003-158732 filed Jun. 3, 2003.

### BACKGROUND OF THE INVENTION

1. Field of Invention

This invention relates to an exposure technology used in lithographic processes for manufacturing various devices, such as semiconductor integrated circuits, image shooting elements, liquid crystal displays and thin film magnetic heads, and particularly useful in reducing OPE (optical proximity errors), which are errors due to optical proximity effects.

2. Description of Related Art

For forming micro-patterns for electronic devices, such as, e.g., semiconductor integrated circuits and liquid crystal displays, a method is used that exposes and transfers (while reducing the size of) a pattern of a reticle (a photomask and the like), as a mask drawn with a pattern to be formed that is proportionally enlarged by 4-5 times, onto a wafer (or a glass plate or the like), as an exposed substrate via a projection optical system. The resolution of the projection optical system has a value that is approximately equal to an exposure wavelength of the exposure light divided by a numerical aperture (NA) of the projection optical system. The numerical aperture (NA) of the projection optical system is a sine (sin) of the maximum incident angle of the illumination luminous flux for exposure onto a wafer multiplied by a refractive index of a medium through which the luminous flux is transmitted.

Therefore, to facilitate miniaturization of semiconductor integrated circuits and the like, the exposure wavelength of a projection exposure apparatus has been shortened. Nowadays, the mainstream of the exposure wavelength is 248 nm using a KrF excimer laser. However, ArF excimer lasers having a shorter wavelength of 193 nm are about to be implemented. Moreover, projection exposure apparatus have been proposed that use an exposure light source in a so-called vacuum ultraviolet region, such as an F₂ laser having an even shorter wavelength of 157 nm, and Ar₂ lasers having a wavelength of 126 nm. Furthermore, because the resolution can be increased not only by shortening the wavelength but also by increasing the numerical aperture (increasing NA) of the projection optical system, developments have been investigated to further increase the NA for the projection optical system. Currently, the most advanced NA for a projection optical system is about 0.8.

On the other hand, as a technology to increase the resolution of a transferred pattern while using the same exposure wavelength and the same NA for a projection optical system, a method has been implemented that uses a so-called phase shift reticle, or a so-called super resolution technology, such as annular control (see Japanese Laid-Open Patent Application No. 61-91662, for example), dipole illumination and quadrupole illumination (see Japanese Laid-Open Patent Application Nos. 4-101148 and 4-225357, for example) that control the distribution of incident angles of the illumination flux onto a reticle to a predetermined distribution. Among the phase shift reticles, a spatial frequency modulation type phase shift reticle (alternating phase shift reticle) is especially effective in both reducing a pattern spacing (pitch) of the transferred pattern and reducing a pattern line width, and has been used for manufacturing high-speed devices, such as a CPU (central processing unit) that requires micro-linewidth patterns.

Increasing the NA for a projection optical system can be achieved easily for an optical system that has a small field of view (exposure field). However, for a projection exposure apparatus, the process performance (throughput) increases with a larger exposure field (a region that can be transferred at one exposure operation). Therefore, scanning type exposure apparatus (e.g., scanning steppers) that use a projection optical system with a small field of view and a large NA and that scan a mask and a wafer relative to each other during exposure while maintaining a predetermined image forming relationship between them to obtain a substantially large exposure field, have been used more recently.

Generally, the projection optical system used in the scanning type exposure apparatus has a rectangular image field (exposure field) that is long in one direction and short in another direction orthogonal thereto. The optical system for such an exposure system may be a reflection optical system, but it also is common to use the refractive optical system down to an exposure wavelength of 193 nm (ArF excimer laser). In such a case, the rectangular exposure field is generally a rectangle, of which a diagonal is a diameter passing though a center of a circle that is essentially a well-imaged range of the refractive optical system composed of a combination of circular lenses, and that is inscribed inside the circle. The reason is that such a rectangular exposure field is most efficient since the length of the long sides of the exposure field can be maximized. In this case, although the length of the short sides of the exposure field is reduced, by performing the relative scanning of the reticle and substrate in the direction of the short sides of the exposure field, the exposure field in that direction can be substantially expanded. Therefore, in the scanning type exposure apparatus, since the size of the exposure field exposed on a wafer at one scanning exposure is a product of a length of the long sides of the exposure field and the scanned distance, a large exposure field can be exposed even with a small projection optical system.

### SUMMARY OF THE INVENTION

As described above, the use of a phase shift reticle is extremely effective for increasing the resolution. However, in order to sufficiently utilize its performance, it is desirable to use illumination light with a high spatial coherency. The spatial coherency is the degree of coherency between the illumination light distributed on two different points. The smaller the incident angle range of the illumination light is, the higher the spatial coherency becomes. Thus, when using a phase shift reticle, a so-called σ value (a value of NA of illumination light (NAI) that illuminates the reticle divided by NA of the projection optical system (NAR) on the reticle side), which is the coherence factor of the illumination light, preferably should be equal to or less than approximately 0.3. In addition, to support additional miniaturization of the semiconductor integrated circuits and the like in the future, it is desirable that the illumination be performed with illumination light having a σ value of about 0.15 to secure the required depth of focus while further increasing the resolution.

However, if such a small σ value, that is, illumination light with high coherency, is used, the coherency between the illumination light illuminated at a certain pattern and the illumination light in areas around the pattern becomes extremely high. As a result, a problem called OPE (optical proximity error), which is an error due to optical proximity effect, occurs. This is a phenomenon in which the intensity of the transferred image of a predetermined pattern varies, which causes the transferred line width to change (i.e., vary) because of the existence of another pattern near the predetermined pattern.

Since the line width variation among the patterns strongly affects performance of high-speed operation of an LSI (Large-Scale Integrated Circuit), for example, such a problem cannot be allowed in an LSI that requires high-speed operation. Therefore, a method called OPC (optical proximity correction) has been implemented, which is a method that estimates the generated OPE by using an optical simulation, from optical conditions, such as an exposure wavelength, an NA for a projection optical system, illumination conditions (e.g., σ value) and the like, and a pattern layout, and corrects the estimated error by increasing or decreasing the actual line width of the pattern on a reticle.

A range of a pattern to be considered for correction using OPC is the range in which the illumination light illuminated on the reticle has coherency. When the σ value of the illumination light to be used is approximately 0.3 of the current state, the range is an area having a radius that is approximately 0.61×exposure wavelength/(NAR×0.3). On the other hand, when the σ value of the illumination light becomes 0.15, the range increases to an area having a radius that is approximately 0.61×exposure wavelength/(NAR×0.15). As a result, the size of the pattern area to be considered becomes four times as large, and since the amount of the OPE increases, the amount of correction by OPC also increases. Because of this, there is a problem of increase in time required for the optical simulation when correcting using OPC and an increase in the costs for correction, which leads to the increase in costs for the reticle.

Moreover, if the σ value of the illumination light becomes about 0.15, a problem occurs that sufficient depth of focus cannot be obtained for a pattern having a predetermined pitch even if an alternating phase shift reticle is used. Thus, measures are desirable when designing electronic circuits for an LSI, such as establishing a design rule that prohibits the pattern from being arranged with any specific pitches. This substantially reduces the degree of integration of the LSI and makes the circuit design more complicated, resulting in increase in the time for designing the circuit and the design cost.

This invention considers these problems and has as one object, the provision of an exposure technology that can improve errors (OPE characteristics) generated due to optical proximity effects.

In addition, this invention has as another object, the provision of an exposure technology that can improve the OPE characteristics and prevent the decreasing of depth of focus with a pattern having a predetermined pitch, when using, for example, an alternating phase shift reticle.

Moreover, this invention has as another object, the provision of a device manufacturing technology that uses the above-described exposure technology to manufacture high performance electronic devices at low cost.

An exposure method according to one aspect of this invention illuminates a pattern of a mask with illumination light and transfers an image of the pattern onto a substrate via a projection optical system. At least a part of the mask pattern is a pattern having a longitudinal direction extending in a first direction, and an incident angle range in the first direction of the illumination light illuminated onto the mask is wider than the incident angle range in a second direction orthogonal to the first direction of the illumination light illuminated onto the mask.

According to this aspect of the invention, an imaging beam that has passed through a pattern (pattern for transferring) having a longitudinal direction in the first direction on the mask is distributed in a region on a pupil plane of a projection optical system that has the first direction wider than the second direction. In addition, in the region on the pupil plane, a numerical aperture for the second direction becomes substantially larger near an optical axis than at the periphery thereof Therefore, the images formed on the substrate are an incoherent summation (summation based on intensity) of optical images formed by substantially different numerical apertures. Thus, the spatial coherency of an image on the substrate is reduced due to an averaging effect, and fluctuations due to changes in a pitch of the transferred line width are reduced, resulting in improvement of OPE (optical proximity error) effects that are errors due to optical proximity effects.

As discussed above, it is preferable that the incident angle range of the illumination light to the mask has an effective σ value for the first direction that is different than an effective σ value for the second direction. In particular, for the incident angle range of the illumination light with respect to the mask, the effective σ value for the first direction preferably is at least 0.6, and the effective σ value for the second direction preferably is not more than 0.3 and greater than 0.

In this case, the effective σ value of the illumination light in a predetermined direction on the mask is σ value obtained by multiplying the sine (sin) of the maximum value of the incident angle of the illumination onto the mask in the predetermined direction and the refractive index of the medium, divided by the numerical aperture on the mask side of the projection optical system in the predetermined direction. Therefore, if the effective σ value of the illumination light is larger in the first direction than in the second direction, when the refractive index of the medium above and below the mask is substantially equal, the incident angle range in the first direction preferably is wider than the incident angle range in the second direction. Moreover, by setting the effective σ value in the second direction not more than 0.3, high resolution with respect to the second direction can be obtained by a concept similar to that of the so-called small σ illumination.

Furthermore, it is preferable that, for the incident angle range of the illumination light to the mask, the effective σ value is at least 0.7 in the first direction, and not more than 0.2 in the second direction. By doing this, the resolution is further increased, and the OPE characteristics are further improved. It is preferable that at least a part of the mask pattern is an alternating phase shift pattern having a longitudinal direction in the first direction. By doing this, the OPE characteristics are improved, while decreasing of DOF in a pattern having a predetermined pitch can be prevented.

According to another aspect of this invention, the incident angle range of the illumination light illuminated onto the mask is adjusted by an intensity distribution adjusting member.

In addition, the intensity distribution adjusting member can be an aperture diaphragm positioned on or adjacent to a pupil plane of an illumination optical system that illuminates the mask with the illumination light, and that has a rectangular or oval opening. By establishing a shape of an aperture for the illumination aperture diaphragm, the incident angle range of illumination light, or the effective σ value in the first and second directions, can be easily set at a predetermined condition.

Furthermore, it is preferable that a polarization condition of the illumination light be set: (1) in a condition in which a main component of the light is a linearly polarized light and a direction of its electric field coincides with the first direction, or (2) in a condition in which a main component of the light is a linearly polarized light and a direction of its electric field coincides with the longitudinal direction of the aperture in the illumination diaphragm. By doing this, the image forming performance further improves.

Moreover, the intensity distribution with respect to the incident angle of the illumination light to the mask in the first direction can be made strong at both ends of the incident angle range and weak in the middle of the incident angle range. By doing this, the OPE characteristics can be further improved.

In this case, the intensity distribution at both ends of the incident angle range is preferably made 1.5 to 3 times as much as the intensity distribution at the middle of the incident angle range.

Furthermore, it is preferable that a projection optical system with a rectangular field having long sides in the first direction and an illumination optical system with a rectangular illumination field having long sides in the first direction are used, and that the mask and the substrate are exposed while being synchronously scanned in the second direction, while maintaining an image forming relationship through the projection optical system. As a result, the pattern having the longitudinal direction in the first direction is projected as is by the projection optical system having a rectangular field, and the pattern on the area wider than the illumination field in the second direction is projected on the substrate by the scanning exposure process.

An exposure method according to another aspect of this invention illuminates a pattern of a mask with illumination light and transfers an image of the pattern onto a substrate via a projection optical system. The substrate is exposed by multiple exposures that are by the first exposure method described above, and a second exposure using an exposure method different from the first exposure method.

According to this aspect of the invention, various patterns can be transferred onto the substrate at high resolution for various patterns.

In addition an exposure apparatus of one aspect of the invention includes an illumination optical system that illuminates a mask with illumination light and a projection optical system that transfers an image of a pattern of the mask onto a substrate, wherein an incident angle range in the first direction of the illumination light illuminated onto the mask is wider than an incident angle range in a second direction orthogonal to the first direction of the illumination light illuminated onto the mask.

According to this aspect of the invention, the OPE characteristics of the image on the pattern are improved when, for example, a pattern having a longitudinal direction in the first direction is formed on the mask. In addition, when an alternating phase shift pattern having a longitudinal direction is formed on the mask, the OPE characteristics are improved, and decreasing of DOF can be prevented with a pattern having a predetermined pitch.

The incident angle range of the illumination light illuminated onto the mask preferably has an effective σ value for the first direction that is different from an effective σ value for the second direction. In particular, it is preferable that for the incident angle range of the illumination light illuminated onto the mask, the effective σ value for the first direction is at least 0.6, and that the effective σ value for the second direction is set not more than 0.3 and greater than 0.

As a result, the incident angle range in the first direction becomes wider than that in the second direction. In addition, by setting the effective σ value in the second direction to not more than 0.3, high resolution can be obtained similarly to the small σ illumination.

In this case, it is preferable that for the incident angle range of the illumination light illuminated onto the mask, the effective σ value for the first direction is at least 0.7, and the effective σ value for the second direction is not more than 0.2. By doing this, even higher resolution can be obtained, and the OPE characteristics can be further improved.

Moreover, it is preferable to have an intensity distribution adjusting member for adjusting the incident angle range of the illumination light illuminated onto the mask.

The intensity distribution adjusting member can be an illumination system aperture diaphragm positioned on or adjacent to a pupil plane of an illumination optical system and provided with a rectangular or oval opening. By this aperture diaphragm in the illumination system, the incident angle range and the effective σ value of the illumination light can be easily set at a predetermined condition in the two directions.

Furthermore, it is preferable that the illumination optical system has: (1) a polarization control member that makes a polarization condition of a main component of the illumination light as a linearly polarized light in which a direction of its electric field coincides with the first direction, or (2) a polarization control member that makes a polarization condition of the main component of the illumination light as a linearly polarized light in which a direction of its electric field coincides with the longitudinal directions of the aperture provided at the aperture diaphragm in the illumination system. As a result, the image forming performance can be further improved.

In addition, the intensity distribution with respect to the incident angle of the illumination light illuminated onto the mask in the first direction is preferably strong at both ends of the incident angle range and weak in the middle of the incident angle range.

In this case, it is preferable that the intensity distribution at both ends of the incident angle range is made 1.5 to 3 times as much as the intensity distribution at the middle of the incident angle range.

It is preferable that the illumination optical system has a first illumination condition variable mechanism that can vary the incident angle of the illumination light within the incident angle range.

Furthermore, it is preferable that the illumination optical system has a second illumination condition variable mechanism that can make the incident angle of the illumination light outside of the above range of incident angle.

In this case, it is preferable that the illumination condition that is set by the second illumination condition variable mechanism includes annular illumination, dipole illumination or quadrupole illumination.

It also is preferable to have a stage mechanism that synchronously scans the mask and the substrate while maintaining a predetermined relationship therebetween for forming images through the projection optical system, and that a direction of the synchronous scanning matches the second direction.

In addition, it is preferable that an exposure field of the projection optical system has a rectangular shape having long sides in the first direction, and an illumination field of the illumination optical system has a rectangular shape having long sides in the first direction. As a result, the pattern having the longitudinal direction in the first direction is projected as is by the projection optical system.

Furthermore, a device manufacturing method of aspects of this invention includes a step of transferring a device pattern onto a substrate by using any of the exposure methods described herein. Using this invention, devices can be mass-produced with high accuracy.

### BRIEF DESCRIPTION OF THE DRAWINGS

The invention will be described with reference to the following drawings in which like reference numerals designate like parts, and wherein:

FIG. 1 is a diagram showing a part of a schematic structure of an exemplary projection exposure apparatus according to an embodiment of this invention;

FIG. 2 is a perspective view showing a simplified optical system from an illumination aperture diaphragm 11 to a reticle R shown in FIG. 1;

FIG. 3A is a plan view showing an illumination aperture diaphragm 11a in FIG. 2;

FIG. 3B is a view of the simplified optical system in FIG. 2 seen from the Y direction;

FIG. 3C is a view of the simplified optical system in FIG. 2 seen from the X direction;

FIG. 4A is a plan view showing a reticle on which a pattern appropriate for an exposure using the projection exposure apparatus of the example is drawn;

FIG. 4B is a plan view showing a reticle on which a pattern that tends to be affected by aberrations of the projection optical system at both ends of the image field when exposed by the projection exposure apparatus is drawn;

FIG. 5A is a plan view showing an example of an alternating type phase shift reticle;

FIG. 5B is a drawing showing an example of an intensity distribution of an image corresponding to a part along A-A′ of FIG. 5A;

FIG. 6A is a plan view showing the illumination aperture diaphragm 11a of FIG. 3A;

FIG. 6B is a drawing showing uniform light-amount distributions of the opening 12a in the illumination aperture diaphragm 11a;

FIG. 6C is a drawing showing a light-amount distribution in which the light-amount increases more in the peripheral areas than at the center part of the opening 12a;

FIGS. 7A and 7B are examples of a result of calculation of the transfer line width PW and DOF (depth of focus) with respect to a pattern pitch PT, determined using an optical simulation that assumes the use of illumination conditions of σx=0.85 and σy=0.15 according to one embodiment of this invention;

FIGS. 8A and 8B are examples of a result of calculation of the transfer line width PW and DOF (depth of focus) with respect to a pattern pitch PT, determined using an optical simulation under the same σ value conditions as the examples of FIGS. 7A-7B and that uses the distribution shown in FIG. 6C as the light-amount distribution of the opening;

FIG. 9A is a plan view showing the illumination aperture diaphragm 11a in FIG. 3A;

FIG. 9B is a plan view showing an example of a pattern of a reticle R;

FIG. 9C is a diagram showing the pupil plane of the projection optical system 23;

FIGS. 10A and 10B are diagrams showing an example of a result of calculating a transferred line width PW and a DOF (depth of focus) with respect to the pattern pitch PT, using an optical simulation that assumes the use of a conventional illumination (σ=0.15);

FIGS. 11A and 11B are diagrams showing an example of a result of calculating a transferred line width PW and a DOF (depth of focus) with respect to the pattern pitch PT, using an optical simulation that assumes the use of a conventional illumination (σ=0.30);

FIG. 12A is a diagram showings a shape of a reticle pattern used for studying the optical simulation;

FIG. 12B is a diagram showing a resist pattern RS in which the pattern of FIG. 12A is formed on the wafer W;

FIGS. 13A and 13B are diagrams showing relationships between the line width PW1 (vertical axis) of the resist pattern CA, and a position X1 (horizontal axis) in the X direction, when normal illumination at σ=0.15, which is the conventional exposure method, is used;

FIGS. 14A and 14B are diagrams showing an example of an optical simulation result that assumes the use of the conventional illumination (σ=0.30);

FIGS. 15A and 15B are diagrams showing an example of an optical simulation result that assumes the use of illumination conditions at σ=0.85 and σ=0.15 in some embodiments of this invention; and

FIG. 16 is a diagram showing an example of a lithographic process for manufacturing a semiconductor device using a projection exposure apparatus of embodiments of this invention.

### DETAILED DESCRIPTION OF PREFERRED EMBODIMENTS

Exemplary embodiments of this invention are explained with reference to the drawings. One embodiment shows a case in which this invention is used when exposure is performed with a scanning exposure type projection exposure apparatus (scanning-type exposure apparatus) that uses a step-and-scan method.

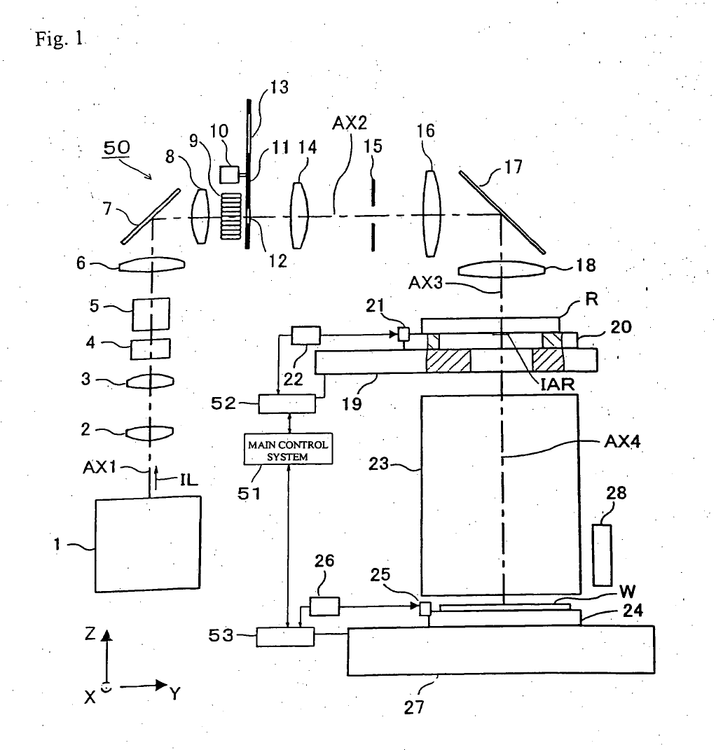

FIG. 1 is a diagram showing a section of part of a projection exposure apparatus of this example. In FIG. 1, an excimer laser light source, such as a KrF (wavelength 247 nm) or an ArF (wavelength 193 nm) laser, is used as an exposure light source 1. As the exposure light source, an F₂ (fluorine) laser light source (wavelength 157 nm), a Kr₂ laser light source (wavelength 146 nm), an Ar₂ laser light source (wavelength 126 nm), a harmonic generating light source using a YAG laser, a harmonic generating device using a solid-state laser (e.g., a semiconductor laser), or a lamp with a line spectrum also may be used.

Exposure illumination light (exposure light) IL irradiated as an exposure beam from the exposure light source 1 enters a polarization control member 4 via relay lenses 2 and 3 along an optical axis AX1. Details of the polarization control member 4 will be described later. The illumination light IL that has passed through the polarization control member 4 enters a first irradiance uniformizing member 5 that functions as an optical integrator (uniformizer or homogenizer). In this example, a fly eye lens (fly eye integrator), for example, is used as the irradiance uniformizing member 5. However, an internal reflection type integrator (e.g., so-called glass rod) or a diffractive optical element (DOE) and the like, such as a diffractive grating, may be used instead. The illumination light IL that has been irradiated from the first irradiance uniformizing member 5 reaches an optical path redirecting mirror 7 via a relay lens 6. The illumination light IL reflected by the mirror 7 enters a second irradiance uniformizing member 9 that functions as an optical integrator, via a relay lens 8 along an optical axis AX2. As the irradiance uniformizing member 9, a fly eye lens is used in this example. However, an internal reflection type integrator or a diffractive optical element (DOE) may be used instead.

On the exit side (exit side focal plane) of the second irradiance uniformizing member 9, a revolving illumination aperture diaphragm 11 is disposed for switching various shapes of apertures in the illumination system (so-called σ diaphragm). On the illumination aperture diaphragm 11, which functions as an intensity distribution adjustment member, in addition to an opening 12 (described later) for reducing error due to optical proximity effects, an opening 13 is positioned that is composed of a circular diaphragm having a variable diaphragm (iris diaphragm), as well as an annular diaphragm, and/or a modified illumination (e.g., dipolar illumination and quadrupole illumination) diaphragm having a plurality of openings. The apparatus is structured such that, by driving the illumination aperture diaphragm 11 using a turret type switching mechanism 10, for example, under a control of a main control system 51 that generally controls the operation of the entire apparatus, any of the openings (σ diaphragms) can be positioned on the exit side of the irradiance uniformizing member 9. In the condition shown in FIG. 1, the opening 12 is positioned on the exit side of the irradiance uniformizing member 9. The illumination aperture diaphragm 11 and the switching mechanism 10 correspond to first and second illumination condition variable mechanisms of some aspects of this invention.

The illumination light IL radiated from the opening 12 reaches an optical path redirecting mirror 17 via a relay lens 14, an illumination field diaphragm 15, and a condenser lens 16 along the optical axis AX2. The illumination light IL reflected by the mirror 17 illuminates with a uniform illumination distribution a rectangular illumination field IAR on a pattern side (lower surface) of a reticle R that functions as a mask, via a condenser lens 18 along an optical axis AX3. In this example, the illumination optical system 50 is structured from the relay lenses 2 and 3, the polarization control member 4, the first irradiance uniformizing member 5, the relay lenses 6 and 8, the mirrors 7 and 17, the second irradiance uniformizing member 9, the opening 12 (or other diaphragms), the relay lens 14, the illumination field diaphragm 15, and the condenser lenses 16 and 18.

The light path redirecting mirrors 7 and 17 are not necessary for the optical performance. However, they are positioned at appropriate locations within the illumination optical system 50 for the purpose of saving space since the total height of the projection exposure apparatus would increase if the optical axes AX1, AX2 and AX3 of the illumination optical system 50 were positioned linearly. The optical axis AX1 of the illumination optical system 50 becomes the optical axis AX2 as it is redirected by the mirror 7, and the optical axis AX2 becomes the optical axis AX3 as it is redirected by the mirror 17. Moreover, because the projection exposure apparatus of this example is a scanning exposure type, the illumination field diaphragm 15 is a fixed field diaphragm that regulates the shape of the illumination field IAR on the reticle R. Other than fixed field diaphragm 15, a variable field diaphragm (not shown in the figures) may be positioned for gradually opening and closing the illumination field IAR in the scanning direction so that unnecessary parts (of the reticle and/or the substrate) are not exposed when starting and ending each scanning exposure. The latter variable field diaphragm also may be used for restricting the illumination field IAR in a non-scanning direction orthogonal to the scanning direction.

Under the illumination light IL, the pattern within the illumination field IAR on the reticle R is reduced and projected onto an exposure region in an area for one shot on a wafer W (substrate) as a substrate to be exposed, on which a photoresist is applied, at a projection magnification β (where β is ¼, ⅕, etc.) through the projection optical system 23, which is telecentric on both of wafer side and reticle side, for example. The exposure field (image field) has a narrow and long shape extending in the non-scanning direction, which is orthogonal to the scanning direction, of the wafer conjugate with the illumination field IAR. The reticle R and the wafer W may be referred to as the first and second objects. The wafer W typically is a disc-shaped substrate made from a semiconductor (e.g., silicon), an SOI (silicon on insulator) or the like, that has a diameter of 200-300 mm. The projection optical system 23 of this embodiment may be a refractive optical system, for example. Below, explanations will be made in which a Z axis is taken parallel with an optical axis AX4 of the projection optical system 23, a Y axis is taken in a plane (XY plane) perpendicular to the Z axis and along the scanning direction of the reticle R and the wafer W at the time of scanning exposure, and an X axis is taken along the non-scanning direction. In this embodiment, the XY plane is a substantially horizontal plane. In addition, the optical axis AX4 of the projection optical system 23 coincides with the optical axis AX3 of the illumination optical system 50 on the reticle R.

First, the reticle R, on which a pattern to be exposed and transferred is formed, is held by vacuum chucking on a reticle stage 20. The scanning of the reticle is performed by moving the reticle stage 20 on a reticle base 19 at a constant speed in the Y direction and by micro-moving the reticle stage 20 in rotational directions about the X, Y and Z axes to correct synchronous errors. Positions and rotation angles of the reticle stage 20 in the X and Y directions are measured by a movable mirror 21 provided thereon and a laser interferometer 22. Based on the measured values and control information from the main control system 51, a reticle stage driving system 52 controls the position and speed of the reticle stage 20 via a drive mechanism (not shown in the figures), such as a linear motor. Above the periphery of the reticle R, a reticle alignment microscope (not shown in the figures) for aligning the reticle is positioned.

On the other hand, the wafer is held on a wafer holder (not shown in the figures), and the wafer holder is held on the wafer stage 24. The wafer stage 24 is mounted on a wafer base 27 and is movable at a constant speed in the Y direction and also movable in the X and Y directions with stepping motions. In addition, the wafer stage 24 has a Z leveling mechanism for making the surface of the wafer W coincide with an image plane of the projection optical system 23 based on values measured by an auto-focus sensor not shown in the figures. Positions and rotational angles of the wafer stage 24 in the X and Y directions are measured by a movable mirror 25 provided thereon and a laser interferometer 26. Based on the measured values and the control information from the main control system 51, a wafer stage driving system 53 controls the position and speed of the wafer stage 24 via a drive mechanism (not shown in the figures), such as a linear motor.

The reticle stage 20, the reticle base 19, the wafer stage 24, the wafer base 27 and the drive mechanisms, such as a linear motor, not shown in the figure, are an example of a stage mechanism applicable to this invention. In addition, near the projection optical system 23, an FIA (field image alignment) type alignment sensor 28, for example, that uses an off-axis method that detects the position of an alignment mark on the wafer W, is positioned for wafer alignment. The FIA type alignment sensor is disclosed in Japanese Laid-Open Patent Application No. 7-183186, for example.

At the time of scanning exposure by the projection exposure apparatus of this embodiment, an operation that synchronously scans the reticle R and the wafer W for one shot area by driving the reticle stage 20 and the wafer stage 24 as the illumination light IL is illuminated on the illumination field IAR on the reticle R, and an operation that stops the illumination of the illumination light IL and step-moves the wafer W by driving the wafer stage 24, are repeated. A ratio of the scanning speed between the wafer stage 24 and the reticle stage 20 at the time of synchronous scanning is equal to the projection magnification β (reduction magnification, such as ¼, ⅕ or the like) of the projection optical system 23 to maintain the image-forming relationship between the reticle and the wafer through the projection optical system 23. By these operations, the image of a pattern on the reticle R is exposed and transferred to each of the shot areas on the wafer W according to the step-and-scan method.

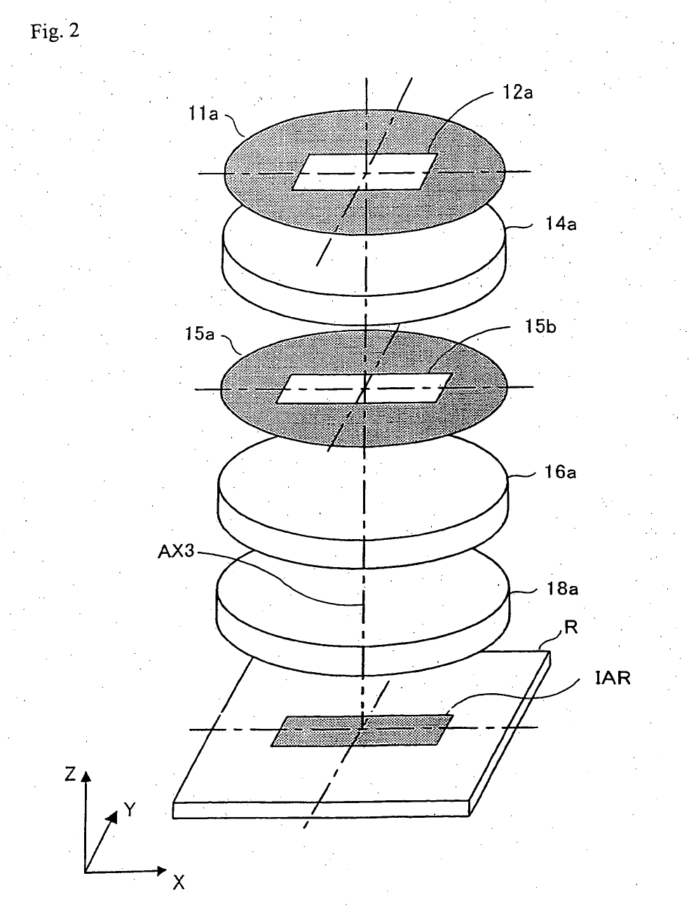

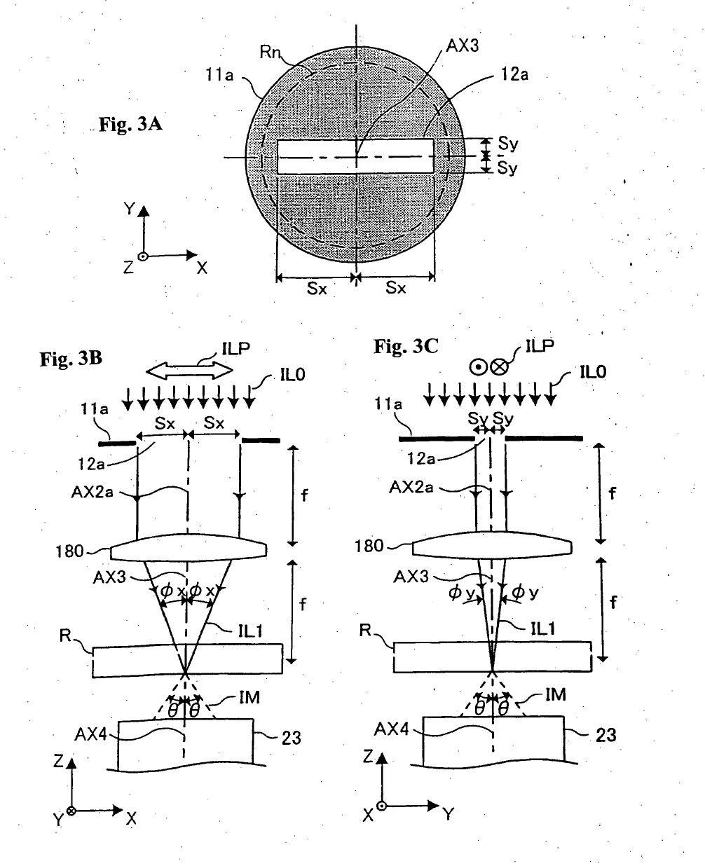

Next, illumination conditions in this example are described in detail. First, by referring to FIGS. 2 and 3, the relationships between the illumination aperture diaphragm 11 (opening 12), the illumination field diaphragm 15 and the reticle R shown in FIG. 1 are described.

FIG. 2 is an enlarged view showing members from the illumination aperture diaphragm 11 to the reticle R in the illumination optical system 50 of the projection exposure apparatus shown in FIG. 1. However, to simplify the explanation, the optical path redirecting mirror 17 in FIG. 1 is omitted, and as a result, the optical axis AX2 of the illumination optical system 50 in FIG. 1 coincides with the optical axis AX3 and is made parallel to the Z axis in FIG. 2, and is referred to as AX2a. In addition, to simplify the explanation, the illumination aperture diaphragm 11, the opening 12, the relay lens 14, the illumination field diaphragm 15, and the condenser lenses 16 and 18 shown in FIG. 1 are referred to with the letter a as an illumination aperture diaphragm 11a, an opening 12a, a relay lens 14a, an illumination field diaphragm 15a, and condenser lenses 16a and 18a. Structures and functions of the members in FIG. 1 and the corresponding members in FIG. 2 (and members in FIG. 3 and thereafter) are the same.

As shown in FIG. 2, in the projection exposure apparatus of this embodiment, since the reticle R is scanned in the Y direction when scan-exposed, the exposure field of the projection optical system 23 shown in FIG. 1, that is the illumination field IAR on the reticle, is preferably rectangular having long sides extending in the X direction (non-scanning direction). Therefore, the shape of the opening 15b of the illumination field diaphragm 15a also is rectangular having its long sides extending in the X direction. The illumination light that passes through the opening 15b is irradiated in the rectangular illumination field IAR on the reticle R via the condenser lenses 16a and 18a.

In this embodiment, the shape of the opening 12a on the illumination aperture diaphragm 11a also is made rectangular having its long sides extending in the X direction non-scanning direction) as shown in FIG. 2. The exit side of the second irradiance uniformizing member 9 in FIG. 1 is positioned at or near a Fourier transform plane of the pattern surface on the reticle R, through the relay lens 14a and the condenser lenses 16a and 18a in FIG. 2. The Fourier transform plane with respect to the reticle R in the illumination optical system means a plane in which an incident flux of the illumination that passes through a position remote from the optical axis within the plane by a predetermined distance D incident to the reticle R becomes a substantially parallel flux and enters at an incident angle ψ that satisfies the following relation. This corresponds to a plane generally called a pupil plane of the illumination optical system.

D=f×sin ψ

where f is a synthesized focal length of the relay lens 14a and the condenser lenses 16a and 18a. Because the illumination aperture diaphragm 11a is positioned on or near the exit side of the second irradiance uniformizing member 9 in FIG. 1, that is, the Fourier transform plane (pupil plane) with respect to the reticle R in the illumination optical system 50, the incident angle range of the illumination beam that has passed through opening 12a having the long sides extending in the X direction to the reticle R becomes large in the X direction and small in the Y direction.

FIGS. 3A-3C are diagrams showing relationships between the illumination aperture diaphragm 11a shown in FIG. 2 and the incident angle range of the illumination light IL1 (corresponding to the illumination light IL in FIG. 1) to the reticle R. However, in FIGS. 3B and 3C which correspond to views seen in the Y direction and X direction of FIG. 2, respectively, the relay lens 14a and the condenser lenses 16a and 18a are shown virtually as one condenser lens 180 for the purpose of simplifying the explanation. The distance between the virtual condenser lens 180 and the illumination aperture diaphragm 11a and the distance between the virtual condenser lens 180 and the reticle R are each equal to the focal length f of the virtual condenser lens 180.

FIG. 3A is a plan view of the illumination aperture diaphragm 11a. In FIG. 3A, the rectangular opening 12a having the long sides extending in the X direction (non-scanning direction in this example), which has a half width in the X direction of Sx and a half width in the Y direction of Sy with the optical axis AX3 as the center, is formed on an opaque substrate. In the illumination aperture diaphragm 11a, another opening (not shown in the figures) also is provided. The illumination light IL1 that has passed through the opening 12a enters the reticle R with a predetermined incident angle range by the condenser lens 180 shown in FIGS. 3B and 3C.

With respect to the incident angle range of the illumination light IL1 towards the reticle R, the angle range in the X direction becomes ±φx with the direction of the optical axis AX3 as the center as shown in FIG. 3B, and the angle range in the Y direction becomes ±φy with the direction of the optical axis AX3 as the center as shown in FIG. 3C. The following relationships exist between the size (half width Sx and Sy) of the opening 12a in the illumination aperture diaphragm 11a and the incident angle range of the illumination light IL1 towards the reticle R:

Sx=f×sin φx (1)

Sy=f×sin φy (2)

The incident angle range of the illumination light to the reticle R is generally shown by a coherence factor (so-called σ value). The σ value is a value in which the numerical aperture (NAI) of the illumination light illuminating the reticle is divided by the numerical aperture (NAR) of the projection optical system on the reticle side, as shown below.

σ=NAI/NAR

In this case, the numerical aperture (NAI) of the illumination light illuminating the reticle is a product of a sine of the maximum incident angle (defined as φ) of the illumination light towards the reticle multiplied by a refractive index na of a medium located over the reticle.

NAI=na×sin φ

The numerical aperture (NAR) of the projection optical system on the reticle side is, as shown by broken lines in FIGS. 3B and 3C, σ value in which a sine of the maximum exit angle value θ (=sin θ) of the imaging beam IM that exits from a point on the reticle R is multiplied by the refractive index nb of the medium under the reticle R. That is, the numerical aperture NAR corresponds to a value obtained when the numerical aperture NA of the projection optical system 23 on the wafer W side is multiplied by the projection magnification β from the reticle to the wafer, as described below.

NAR=nb×sin θ

In the normal exposure, the medium above and below the reticle is a gas, and therefore, the refractive indexes na and nb can be substantially recognized as 1. Here, it is considered that the refractive indexes of the medium (gas such as air, nitrogen gas, or rare gas (e.g., helium gas) in this embodiment) above and below the reticle R are equal, and thus na=nb. Therefore, the σ value becomes as follows:

σ=NAI/NAR=sin φ/sin θ

In the conventional projection exposure apparatus, the shape of the opening in the illumination aperture diaphragm 11a is generally a circle having a predetermined radius R. At this time, the incident angle range of the illumination light that has passed the circle to the reticle becomes an angle φ that satisfies the following equation in both the X and Y directions.

R=f×sin φ (3)

In this case, the illumination light at σ=1 is illumination light that satisfies sin φ=sin θ and corresponds to illumination light illuminated from a circular aperture whose radius R1 is

R1=f×sin θ (4)

The illumination light at σ=ε corresponds to illumination light illuminated from a circular aperture whose diameter is Rε (=ε×f×sin θ).

In this embodiment, the incident angle range to the reticle R is defined as follows using the σ value. That is, the sine (sin φx) of the incident angle range (±φx) of the illumination light IL1 in the X direction to the reticle R, divided by the numerical aperture of the projection optical system 23 on the reticle side (NAR=sin θ) becomes the effective σ value σx of the illumination light IL1 in the X direction. The sine (sin φy) of the incident angle range (±φy) of the illumination light IL1 in the Y direction to the reticle R, divided by the numerical aperture of the projection optical system 23 on the reticle side (NAR=sin φy) becomes the effective σ value σy of the illumination light IL1 in the Y direction. The projection optical system 23 is rotationally symmetrical and the numerical aperture thereof is equal in the X and Y directions. At this time, the X and Y directions correspond to the first and second directions, respectively, and the following equations hold:

σx=sin φx/sin θ

σy=sin φy/sin θ

From Equations (1), (2) and (4), σx and σy can be represented as follows using the shape of the opening 12a:

σx=Sx/Rn

σy=Sy/Rn

In the projection exposure apparatus of this embodiment, as described later, it is preferable to set the incident angle range (±φx) of the illumination to the reticle R in the X direction (first direction) wider than the incident angle range (±φy) of the illumination to the reticle R in the Y direction (second direction). That is, in the projection exposure apparatus of this example, it is preferable to set the σx value greater than the σy value. In detail, in this example, it is preferable to set the σx value to at least about 0.6 and the σy value to not more than about 0.3 and greater than 0. It is more preferable in this example to set the σy value equal to at least about 0.7 and the σy value to not more than about 0.2.

Next, improvements of OPE (optical proximity errors) and DOF (depth of focus), by setting an illumination condition of this embodiment are explained using optical simulation results and others. Using conventional small σ illumination, resolution and depth of focus of fine patterns are improved especially with alternating phase shift mask. However, increasing OPE and decreasing DOF of particular patterns with a specific pitch become problems if using conventional small σ illumination. Using illumination condition in which range of incident angle to the reticle R is set at the above-described conditions, that is under the illumination condition of this embodiment, both OPE and DOF issues are resolved while keeping high resolution and large depth of focus of fine patterns.

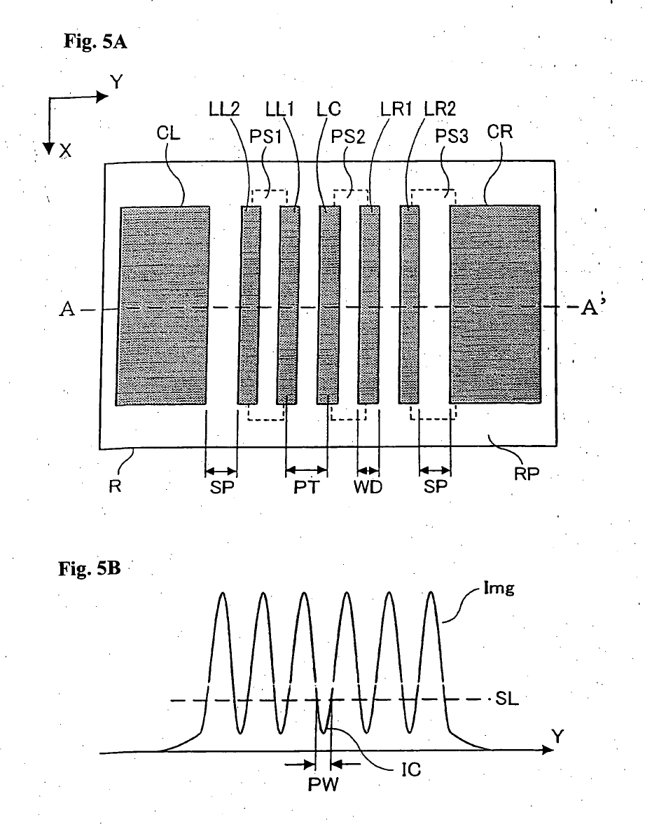

First, a reticle pattern used for examination based on the simulation is described. FIG. 5A is a plan view showing a reticle pattern used in the following simulation. In FIG. 5A, line patterns LC, LL1, LL2, LR1 and LR2 formed by an opaque film, such as chrome, are positioned at a period (pitch) PT in the Y direction on a transmissive reticle substrate RP. The XY coordinates in FIG. 5A are the same as the coordinates shown in FIGS. 1-3. The longitudinal direction of each of the line patterns LC, LL1, LL2, LR1 and LR2 matches the X direction, and the line width in the Y direction, i.e., the lateral direction, is WD. Opaque patterns CL and CR are positioned respectively by a space (a space between neighboring edges of both patterns) SP outside the line patterns LL2 and LR2 located at both ends.

In the spaces between the line patterns LC, LL1, LL2, LR1 and LR2 and the opaque pattern CR, phase shift parts PS1, PS2 and PS3 are formed at every other space, which structures a so-called alternating phase shift pattern (alternating phase shift reticle), by which the phase of the permeated light in the respective parts is shifted by 180° with respect to the permeated light from the other parts of the reticle substrate RP. The phase shift parts PS1, PS2 and PS3 are formed by, for example, engraving the reticle substrate RP by etching.

In the below simulation, the exposure wavelength and the wafer side numerical aperture NA of the projection optical system are set at 193 nm and 0.92, respectively, and the measurements of the reticle pattern in FIG. 5A are, as values converted to the wafer scale considering the projection magnification β (reduction magnification in this example), 50 nm for the line width WD, 140 nm for the space SP, 10 μm for the width of the opaque patterns CR and CL in the Y direction, and 10 μm for the length of each pattern in the X direction. The pitch PT for the line patterns LC, LL1, LL2, LR1 and LR2 is made variable for evaluation of the OPE characteristics and depth of focus at each pitch.

A method for further improving resolution characteristics of a projection exposure apparatus by linearly polarizing the illumination light to the reticle on which a pattern having a longitudinal direction in a predetermined direction is formed as described above is described in Japanese Laid-Open Patent Application No. 5-109601 filed by the Applicant and Reference 1 “Timothy A. Brunner, et al.: “High NA lithographic imaging at Brewster's angle”, SPIE Vol. 4691, pp. 1-24 (2002)”.

To improve the image forming performance with respect to the line patterns LC, LL1, LL2, LR1 and LR2 that have the longitudinal direction extending in the X direction, the linearly polarized light, in which the direction of an electric field coincides with the X direction, is used as the illumination light IL1 in this embodiment as well. By doing so, the polarization direction of the illumination light IL1 coincides with the longitudinal direction of the rectangular opening 12a formed in the illumination aperture diaphragm 11a. This corresponds to a case in which the polarization direction (electric field direction) of the illumination light coincides with a direction ILP in FIGS. 3B and 3C.

The above conditions of polarization of illumination light and patterns are applied in both of the following simulations with the illumination of this embodiment and with the conventional illumination for a reference. Next, a method of the simulation of this embodiment is described.

FIG. 5B shows an intensity distribution Img at a part corresponding to the AA′ line in FIG. 5A determined by an optical simulation, among projected images generated when projecting a reticle pattern shown in FIG. 5A onto a wafer using the projection exposure apparatus of this embodiment. The line width for which the line pattern LC in center of FIG. 5A has been transferred to the wafer can be calculated as a slice width PW determined when a part (dark IC) corresponding to the line pattern LC among the image intensity distribution Img is binarized by a predetermined slice level SL.

Using this method, the simulation evaluations were done under the following methods. The method applied for the evaluation of the OPE characteristics is as follows. Under each of the illumination conditions, an optical image Img of the line pattern LC and the like with the pitch PT 600 nm is calculated at first, then the slice level SL is decided based on the intensity distribution of the optical image Img, wherein the slice width PW of the dark part IC is set at 35 nm.

Next, the intensity distribution Img of the image at each pitch PT is calculated while varying the pitch PT, and the slice width PW of the transferred pattern from the dark IC of each image at the above-described slice level SL is determined. As a result the relationships between the slice width PW of the transferred pattern and the pattern pitch PT are determined.

For the evaluation of DOF (depth of focus), the relationships between the DOF and the pitch PT by varying the pitch of the line pattern LC and the like and calculating the depth of focus at each pitch PT was obtained. An ED-Tree method was applied for calculating the DOF. The ED-Tree method is disclosed in, for example, “Burn J. Lin et al.: “Methods to Print Optical Images at Low-k1 Factors”, SPIE Vol. 1264, pp. 2-13, (1990)”. At that time, the target line width was set at 35 nm. In the evaluation, line width tolerance is set within ±2.8 nm and exposure dose error is set within ±2.5%, respectively for error budgets. Furthermore, width error of mask patterns (line patterns LC and the like) also is considered, and a common DOF estimated by the ED-Tree method is calculated. With respect to the pattern, a pattern having a line width WD of 53 nm in which a manufacturing error of +3 nm was assumed in addition to the reticle line width and a pattern having a line width WD of 47 nm in which a manufacturing error of −3 nm is assumed in addition to the reticle line width, were assumed to consider the effect of width error in actual masks caused in the mask manufacturing process.

In addition, for both the OPE and the DOF, the evaluations were performed for an “isolated line pattern” that is a transformed pattern in which the line patterns LL1, LL2, LR1 and LR2 are removed from the pattern shown in FIG. 5A, and the opaque parts CL and CR are shifted to the center such that both of the spaces between the neighboring edges of the center line pattern CL and opaque patterns LC or RC equal the value of SP.

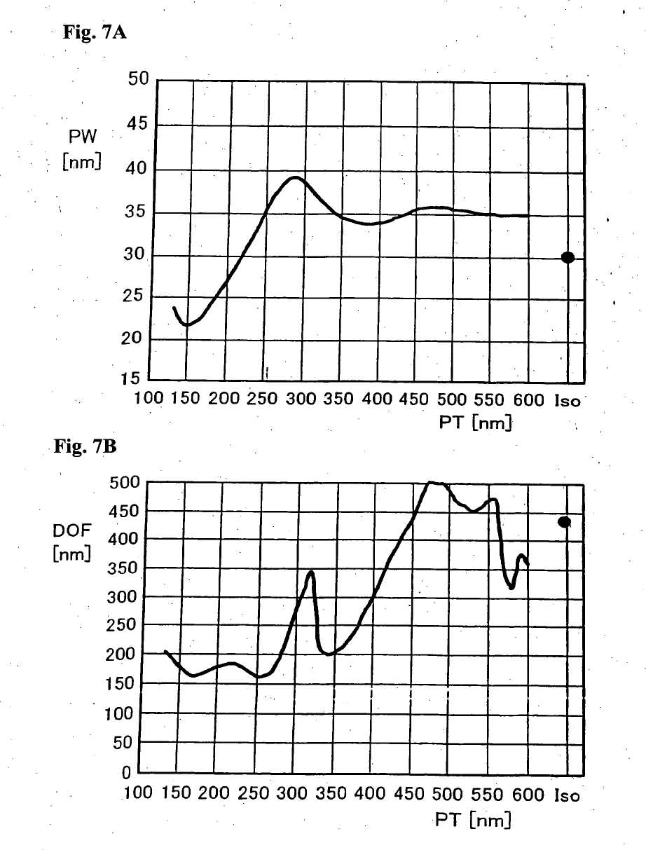

Below describes the results using FIGS. 7, 10 and 11.

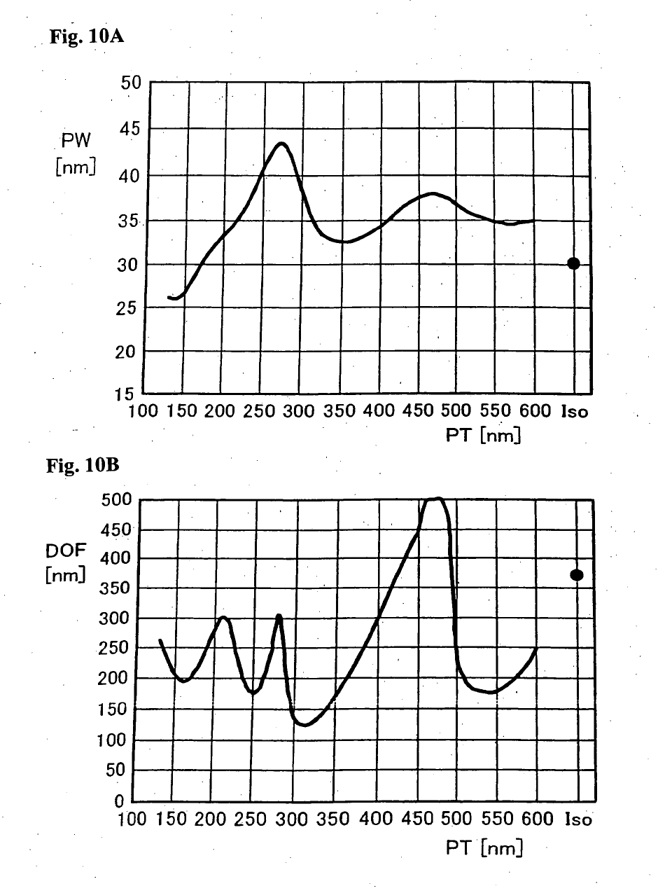

The result of the simulation for the OPE and DOF that assumes the use of normal illumination at σ=0.15 which is the conventional exposure method is as shown in a graph in FIGS. 10A and 10B, respectively.

Since the reticle pattern subject to the exposure is an alternating phase shift pattern, under the small σ illumination at σ=0.15, a large DOF (vertical axis) can be obtained at a micro pitch pattern in which the pattern pitch PT (horizontal axis) is 140 nm-200 nm, as shown in FIG. 10B. However, in the range where the pitch PT is medium, or 290 nm-340 nm, the DOF decreases under 150 nm, and the depth of focus is decreased at a pattern having a so-called specific pitch.

Securing a DOF above 150 nm is extremely important to obtain a yield in the mass production of the LSI, and it is difficult to apply the exposure technology to the mass production with the DOF below 150 nm. As a result, in order to form circuit patterns using the conventional exposure method, it may be necessary to add a restriction in the design (layout) of the circuit pattern and remove patterns that have a pitch in this range.

In addition, as shown in FIG. 10A, changes in the transferred line width PW (vertical axis) that result from changes in the pattern pitch PT (horizontal axis) are large, and the variation in width reaches 10.5 nm with respect to the pattern whose pitch PT is in the range 250 nm-600 nm.

To reduce the OPE, it is possible to correct the line width itself of the pattern on the reticle (correction by OPC (optical proximity correction) which is a method to correct the line width itself of the pattern on the reticle by increasing and/or decreasing the line width) to cancel the change in the line width. However, to do so, it is necessary to determine from the pattern design data what kind of patterns exist around the predetermined reticle pattern, calculate the effects of the neighboring pattern using an optical simulation and the like, and perform the line width correction based on the result of the calculation. In order to do so, enormous calculation time and calculation costs are required, and thus the cost for manufacturing the reticles increases.

In particular, in the small σ illumination at σ=0.15, as shown in FIG. 10A, a relatively large OPE is generated even with a large pitch pattern in which the pitch PT is about 460 nm. This indicates that it is necessary to consider a pattern with a large range (a range reaching a radius of 600 nm as transferred onto a wafer) centering a predetermined pattern at the time of the above-described OPC, and that the number of data to be considered for the OPC and the time required for processing the data further increases.

Iso and a block dot on the right end of the horizontal axis in the graphs shown in FIGS. 10A and 10B indicate results using the isolated line pattern described above and are similar in the following graphs.

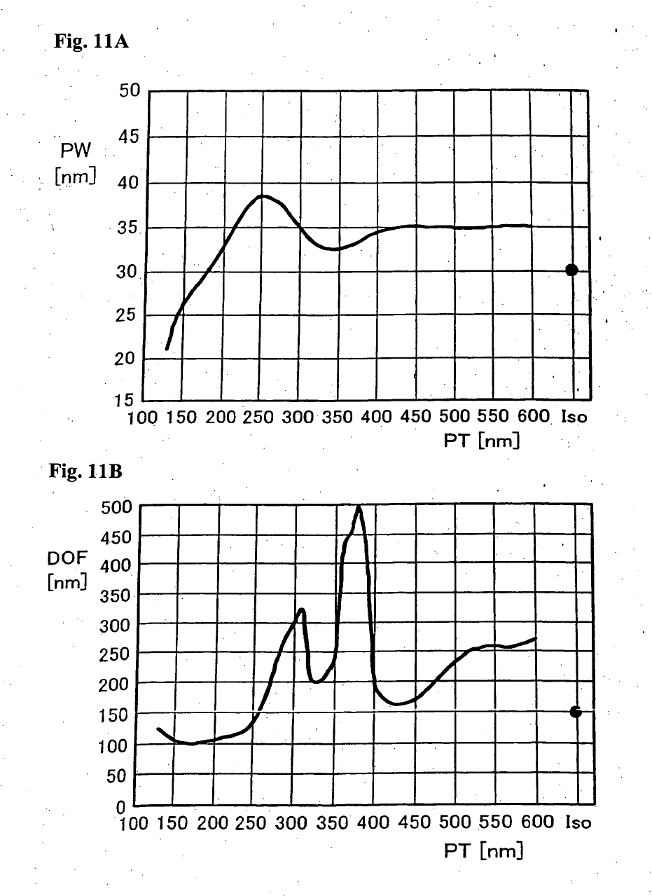

On the other hand, the result of simulation of OPE and DOF that assumes the use of conventional illumination at σ=0.30 are shown respectively in the graphs in FIGS. 11A and 11B. Since the spatial coherency of the illumination light decreased as a result of increasing the illumination σ value to 0.3, the OPE characteristics shown in FIG. 11A improve as the changes in the transferred line width PW with respect to changes in the pitch PT decrease, compared with the graph shown in FIG. 10A. In particular, the variation in line width of the transferred line width PW when the pitch PT is in 250 nm-600 nm range, is reduced to 5.5 nm.

However, the DOF decreases as a result of increase in the illumination a value. Therefore, as shown in FIG. 11B, for a pattern having the pitch PT of 260 nm, the DOF becomes below 150 nm, and therefore the transfer of the micro pitch pattern becomes extremely difficult.

In contrast, results of the simulation of OPE and DOF when σx=0.85 and σy=0.15 are used, as an example of the illumination condition of an embodiment of the invention, are shown in the graphs in FIGS. 7A and 7B.

The OPE characteristics are as shown in FIG. 7A. The variation of the transferred line width PW in the range where the pitch PT is 250 nm-600 nm, is 5.5 nm, which is small and excellent, similar to a case of the conventional illumination at σ=0.3 as shown in FIG. 11A.

In addition, since the variation in the OPE, which should be specially considered, is limited to a pattern in which the pitch PT is within 320 nm with the illumination condition of this embodiment, then neighboring patterns which must be considered in the OPC correction are limited to the patterns which exist within a radius of 320 nm around the target pattern. Therefore, compared to a case in which the conventional illumination at σ=0.15 is used, data volume of patterns to be considered can be reduced greatly, and thus the reduction of OPC time and costs becomes possible.

In the illumination condition of this embodiment, the transferred line width PW becomes narrower in the smaller pitch patterns, especially with a pitch less than 200 nm, and the amount of the difference is 8 nm (35 nm-27 nm) when the pitch PT is 200 nm, for this embodiment. This is larger compared with the conventional illumination at σ=0.15. This means that the OPE effect from a close proximate pattern is large under the illumination condition of this embodiment.

However, because this does not increase the pattern data that needs to be considered for the OPC correction, this does not cause any negative effects such as the increase in the OPC processing time.

Under the illumination condition of this embodiment, as shown in FIG. 7B, the DOF is maintained at equal to or more than 150 nm in the entire range of the pitch PT in the range 140 nm to 600 nm, and in the isolated line pattern shown as Iso on the right end of FIG. 7B.

From the above, under the illumination condition of this embodiment, it can be seen that the exposure and transfer of the patterns having various pitch PT in wide range becomes possible while keeping the OPE low and with a useful depth of focus.

In this example, illumination light having an incident angle range to the reticle that is σy=0.15 and σx=0.85 was used. However, the incident angle range of the illumination light of this example to the reticle is not limited to these values. That is, as long as the illumination has σy equal to or less than 0.3 and σx equal to or more than 0.6, the effects of this invention in achieving good OPE characteristics and depth of focus can be obtained. In addition, when the pitch PT of the reticle pattern to be exposed is more micro, even better effects can be obtained by using illumination light with σy equal to or less than 0.2 and σx equal to or more than 0.7.

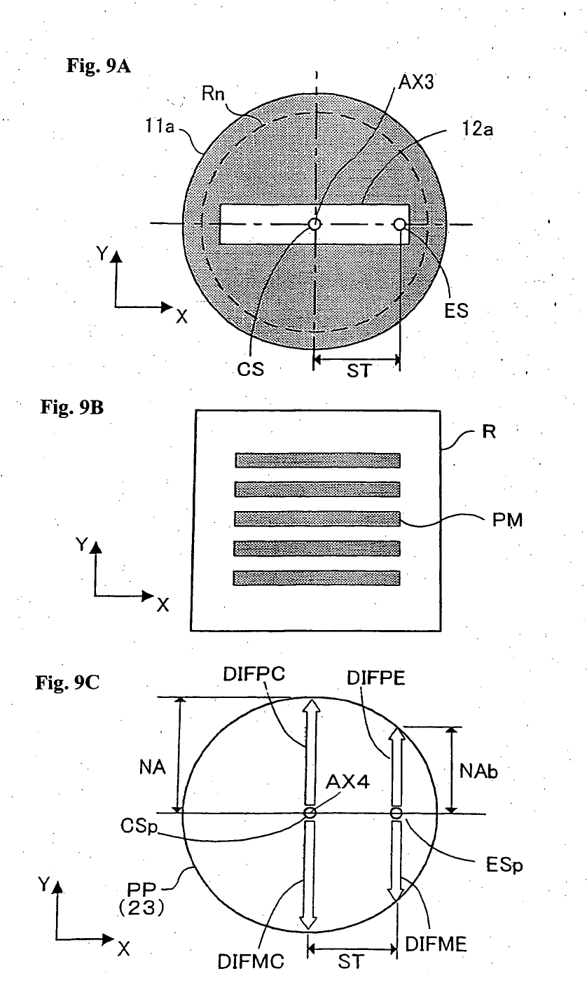

In the simulation as described above, linearly polarized light in which the direction of the electric field coincides with the X direction was used as the illumination light IL. However, the effects of this invention as described above also can be obtained when such linearly polarized light is not used. The reasons why the OPE characteristics and the DOF are improved by the illumination condition of this invention is briefly explained using FIGS. 9A-9C.

FIG. 9A is a drawing showing the illumination aperture diaphragm 11a shown in FIG. 3A. In FIG. 9A, the illumination light existing at a center portion CS located near the optical axis AX3 in the opening 12a has a function similar to the conventional small σ (e.g., σ=0.15) illumination light. This illumination light is illuminated substantially perpendicularly to the reticle R that has a pattern PM having a longitudinal direction extending in the X direction and a frequency in the Y direction as shown in FIG. 9B. Diffracted light is generated from the pattern PM in the Y direction. As shown in FIG. 9C, the diffracted light at the center portion CSp on the optical axis AX4 is distributed on the pupil plane PP of the projection optical system 23 as it expands in the Y direction as indicated by distributions DIFPC and DIFMC. The range of such distributions is limited by the radius of the pupil plane PP, that is NA of the projection optical system 23.

On the other hand, the illumination light exists in end section of opening 12a located at a position remote from the optical axis AX3 by the distance ST towards the right in FIG. 9A becomes incident while it is inclined in the X direction with respect to the reticle pattern PM. As a result, the diffracted light from the reticle pattern PM is generated while it also is inclined in the X direction. Therefore, the diffracted light DIFPE and DIFME are distributed on the pupil plane PP of the projection optical system 23 in FIG. 9C at locations ESp remote from the optical axis AX4 by the distance ST. The distribution in the Y direction is limited by the effective numerical aperture Nab, which is a smaller value than the radius (i.e., NA) of the pupil plane PP.

Images of the reticle pattern PM created by the illumination light that has radiated from the center portion CS and the end portion ES of the opening 12a are both exposed on the wafer W. However, the respective images formed by the respective illumination lights are formed by the optical systems with different effective numerical apertures respectively, as described above. Therefore, because the optical images formed by the different numerical apertures are added incoherently (added based on intensity) to the wafer W, the spatial coherency of the image on the wafer W is reduced by the averaging effect, and the changes resulted from the changes in the pitch PT of the transferred line width PW are reduced, resulting in improvements of the OPE characteristics.

On the other hand, the decreasing of DOF at a specific pitch generated with the conventional small σ illumination is a phenomenon that occurs when the pitch becomes predetermined times (e.g., about 1.5 times) of the exposure wavelength/NA. In this invention, the negative effects with the specific pitch are improved by averaging effect of the virtual superimposing exposure, that is incoherent summation of images formed by substantially different numerical apertures respectively. Therefore, the deterioration of DOF at the specific pitch improves.

As described above, according to this embodiment, by illuminating the illumination light at the most optimum incident angle range to a micro pattern on the reticle, the pattern can be exposed with good OPE characteristics. In addition, the decreasing of DOF in the pattern having a specific pitch, which had been a problem in the conventional small σ illumination, can be prevented. Thus, an exposure having a sufficient depth of focus becomes possible with respect to the entirety of the pattern including patterns of any pitch.

In addition, the averaging (superimposing) using imaging beams having substantially different numerical apertures is not performed only by the illumination light generated from the center portion CS and the circumference section ES of FIG. 9A as described above, but it also is continuously accomplished by the illumination light radiated from intermediate positions (between CS and ES). Moreover, this averaging also is performed by the illumination light radiated from the part on the left side (part in −X direction) from the optical axis AX3 in the opening 12a.

However, the value of the effective numerical aperture NAb in the Y direction with respect to the position ST in the X direction of the end part ES does not vary linearly. The change in the effective numerical aperture with respect to the changes of the position ST is gentle around the optical axis, and the value thereof stays close to the NA.

Because of this, when the distribution of the light amount of the illumination light in the opening 12a is uniform in the X direction, the contribution of the imaging beam having an effective numerical aperture in the Y direction is NA (corresponding to an illumination beam distributed near the optical axis AX3 in the X direction in the opening 12a) becomes large for the averaging, and there may be cases in which the averaging effects using the illumination beam generated from the end part ES in the X direction of the opening 12a cannot be sufficiently obtained.

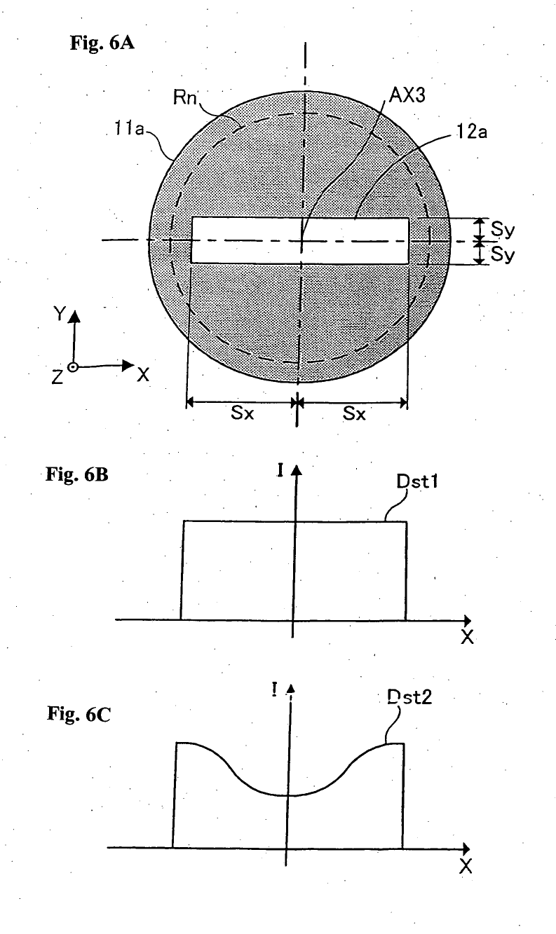

To further increase the averaging effect, the distribution of the light amount of the illumination light transmitted through the opening 12a can be used as the illumination light intensity distribution in which the intensity is high in the end and low in the center with respect to the X direction, as shown in FIG. 6C.

FIG. 6A is a drawing showing the illumination aperture diaphragm 11a and the opening 12a, and FIGS. 6B and 6C are drawings showing the intensity distribution in the X direction of the illumination transmitted from the opening 12a.

In the above-described simulation shown in FIGS. 7A-7B, a uniform light amount distribution Dst1 shown in FIG. 6B was used as the illumination light amount distribution in the X direction.

On the other hand, a light amount distribution Dst2 shown in FIG. 6C is a distribution in which the distribution density of the light amount distribution in the center section in the X direction becomes half of the light amount distribution density in the end parts (both ends) in the X direction, and as described above, further averaging effects can be expected.

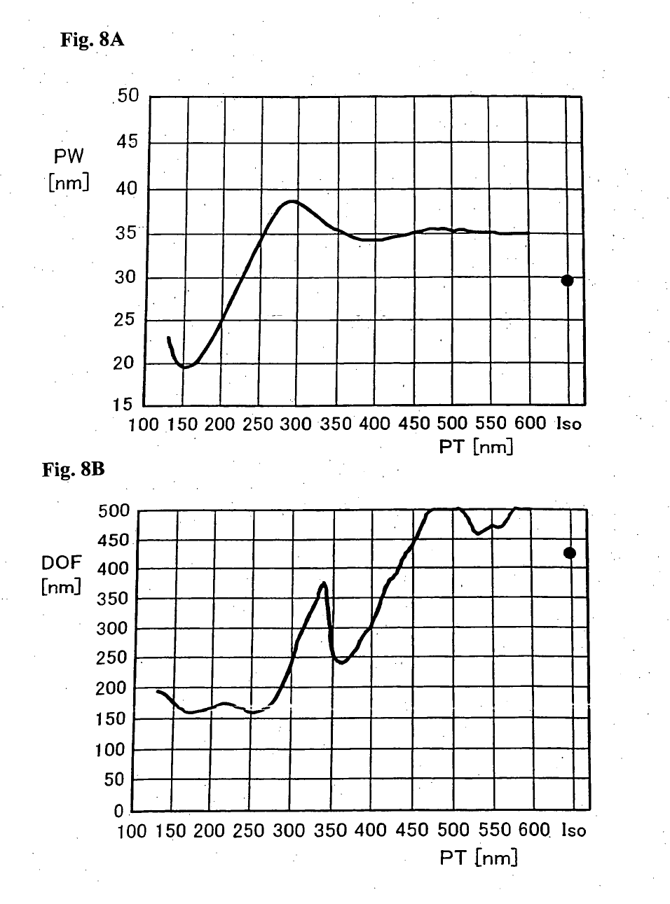

Below, the effects in such a case are described using the simulation results shown in FIGS. 8A-8B. In the below simulation, conditions other than the intensity distribution of the illumination light with respect to the position in the X direction of the illumination light transmitted from the opening 12a, that is, the intensity distribution of the illumination light to the reticle pattern with respect to the incident angle in the X direction, are the same as the conditions for the simulation shown in FIGS. 7A-7B.

FIG. 8A is a graph showing the OPE characteristics, and FIG. 8B is a graph showing the DOF. Under this illumination condition, the variation of the transferred line width PW when the pattern pitch PT changes between 250 nm-600 nm is 45 nm, which shows further improvements in the OPE characteristics than those shown in FIG. 7A.

In addition, also for the DOF, as shown in FIG. 8B, the DOF of more than 150 nm is maintained in the pattern for all of the pattern pitches PT and in the isolated line pattern shown as Iso in the right end of FIG. 8B.

Therefore, it is understood that the OPE characteristics of the pattern to be transferred can be further improved by increasing the illumination light intensity distribution (distribution density) in the illumination beam transmitted from the opening 12a, near both ends of the X direction, by about two times with respect to the area of the center section in the X direction.

The intensity distribution of the illumination light on the opening 12a can be generated by partially changing the transmittance of the opening 12a. For example, the opening 12a with such an intensity distribution can be produced by forming a light-absorbing thin film formed from a metal, such as chrome, or a dielectric on a transmissive substrate, such as glass or quartz glass, while changing the thickness of the thin film depending on the position.

The ratio of the distribution density that is about two times was described above. The invention, however, is not limited to this, but the OPE characteristics that are much better than the case, in which the distribution in the X direction is uniform, can be obtained as long as the ratio is about 1.5-3 times.

In contrast, when the ratio is more than three times, the light amount distribution existing in the center section in the X direction becomes relatively too low, and thus the above-described averaging effects cannot be sufficiently obtained. Therefore, it is difficult to obtain the effects of this aspect of the invention. Of course, the above-described averaging effects also cannot be sufficiently obtained when the light amount distribution near the center section in the X direction, that is, when the illumination light is distributed dispersively in the X direction at positions other than the optical axis AX3.

This example creates the uniformization (averaging) by illuminating the reticle R by the illumination light having a wide incident angle range in the X direction, and thus the shape of the opening 12a is not limited to a rectangle. That is, the opening 12a shown in FIG. 3A does not have to be a rectangle as shown in FIG. 3A, but can be, for example, an oval whose long axis coincides with the X direction and whose short axis coincides with the Y direction. In such a case, it is preferable that a half (half width) of the length of the long axis of the oval is Sx, and a half (half width) of the length of the short axis is Sy.

However, when an oval opening is used, since the width in the Y direction becomes wide in the center section and narrow in the end part in the X direction, the total value of the intensity distribution of the illumination light in the Y direction in the oval opening becomes large in the center section and small in the end part in the X direction. This is opposite from the better distribution shown in FIG. 6C, and thus becomes a distribution in which the averaging effects according to some aspects of this invention become hard to generate. Accordingly, when the oval opening is used, it is preferable to make the illumination light amount distribution per unit area in the opening much stronger in the end part in the X direction.

Furthermore, even if the illumination light is dispersively distributed in the X direction, since the averaging of this example is performed using the illumination light when a part of the illumination is distributed near the optical axis AX3, and when the other illumination light is distributed at the ends of the X direction, the effects of this aspect of the invention can be obtained. In that case, the above-described σx and σy are defined based on the sine of the maximum value of the incident angle in the X direction to the reticle R of the illumination light irradiated from the end of the distribution in the X direction. If these values satisfy the conditions of this example, i.e., 0<σy≦0.3, and σx≧0.6, the effects of this aspect of the invention can be obtained. Moreover, if 0<σy≦0.2, and σx≧0.7 are satisfied, further improvements of the above effects can be obtained.

The projection exposure apparatus of this embodiment can be structured to provide a plurality of openings each having a different transmittance distribution (opening 12 and openings having a transmittance distribution that is varied) in the X direction on the illumination aperture diaphragm 11 in FIG. 1, and to perform exposure while switching a pattern on the reticle R to be exposed by a switching mechanism 10, such as a turret type switching mechanism, depending on the pattern.

In addition, on the illumination aperture diaphragm 11, a plurality of openings 12, 13 and the like, each having a different shape may be provided. The shape of each opening is rectangular as shown in FIG. 3A, and the lengths Sx and Sy of each side are different respectively. These can be switched based on the pattern on the reticle to be exposed.

It also is possible to obtain good averaging effects as described above, by changing the shape of the opening on the pupil plane of the projection optical system. The shape of the opening on the pupil plane PP of the normal projection optical system is circular as shown in FIG. 9C. Because of this, the effective numerical aperture NAb in the Y direction that limits the diffracted light DIFPE and DIFME, which are formed by the illumination beam ES of a part remote by a predetermined distance ST in the X direction from the center in the opening 12a of the aperture diaphragm 11a in the illumination optical system shown in FIG. 9A, does not decrease linearly with respect to the distance ST. However, if the shape of the opening on the pupil plane PP of the projection optical system 23 is made square having vertices at two points separated in the ±X directions and two points separated in the ±Y directions from the optical axis AX4, the effective numerical aperture NAb in the Y direction decreases linearly with respect to the distance ST. Therefore, if such a projection optical system 23 is used, even while the illumination light amount distribution on the opening 12a is made uniform in the X direction, good averaging effects similar to the ones described above can be obtained. To configure the shape of the opening on the pupil plane PP as described above, a diaphragm having an opening of such a shape (square) should be installed on the pupil plane of the projection optical system 23.

However, when exposure is performed also by the conventional exposure method in the projection exposure apparatus of this example, it is preferable to have a variable diaphragm rather than a fixed diaphragm. This can be realized by positioning four variable blades corresponding to each side of the square such that they are movable radially with the optical axis AX4 of the projection optical system 23 as the center.

Furthermore, since a reticle that is not the alternating phase shift reticle shown in FIG. 5A may be exposed in the projection exposure apparatus of this example, it is preferable to place on the illumination aperture diaphragm 11 a circular opening for the normal illumination at σ=0.1-0.9, an annular opening for annular illumination, or an opening for dipole or quadrupole illumination that is appropriate for exposure for the other reticles, and to be able to replaceably use them depending on the reticle R to be exposed.

The configuration of the incident angle range of the illumination light IL1 to the reticle R can be controlled not only by the shape of the opening 12 (or 12a) on the above-described illumination aperture diaphragm 11 (or 11a). For example, if the intensity distribution itself of the illumination light on the exit side of the second irradiance uniformizing member 9 in FIG. 1 can be of a desired shape, the incident angle range of the illumination IL1 to the reticle R can be configured at a desired range, and therefore, the illumination aperture diaphragm 11a and the opening 12 do not have to be used in this case.

To do so, a predetermined diffractive element (grating) could be used as the first irradiance uniformnizing member 5 in FIG. 1, for example. The diffractive pattern formed at the diffractive element is configured such that the diffracted light generated therefrom has a periodicity and a direction so that it is distributed at the above-described predetermined shape on the incident side of the second irradiance uniformizing member 9. In addition, in order to be able to control the generation of the 0th-order diffracted light (nondiffracted light), it is preferable to use a phase grating as the diffractive element.

In addition, the exposure can be accomplished by providing a plurality of such diffractive elements at the position of the first irradiance uniformizing member 5 in FIG. 1, providing a diffractive element changing mechanism that allows them to be interchangeably provided at the position of the optical axis AX1 of the illumination optical system 50, and changing the diffractive element depending on the pattern on the reticle R to be exposed. At this time, it is preferable that each of the diffractive elements includes at least one condition of this example, which is that σy is equal to or less than 0.3 and σx is equal to or more than 0.6, and supports one of the normal illumination, annular illumination, the dipole illumination and the quadrupole illumination.

It is possible to form a predetermined illumination light intensity distribution at the incident side of the second irradiance uniformizing member 9, even if a polyhedron prism, a cone prism or a multi-plane mirror is used.

In the above embodiment, if the relay lenses 6 and 8 between the first irradiance uniformizing member 5 and the second irradiance uniformizing member 9 that use the diffractive elements, are made as a zooming optical system, the intensity distribution of the illumination light formed on the incident side of the second irradiance uniformizing member 9 by the diffraction of the diffractive elements, can be enlarged or reduced with the optical axis AX2 as the center in the X and Z directions in FIG. 1. As a result, the shape of the intensity distribution of the illumination light formed on the exit side of the second irradiance uniformizing member 9 (i.e., pupil plane of the illumination optical system 50 or near the pupil plane), that is, the incident angle range of the illumination light to the reticle, can be made variable with more flexibility.

Furthermore, by making the relay lenses 2 and 3 between the exposure light source 1 and the first irradiance uniformizing member 5 as a zooming optical system, the flexibility for configuring the incident angle range of the illumination light to the reticle R can be further increased.

In the projection exposure apparatus shown in FIG. 1, a fly eye lens is used as the second irradiance uniformizing member 9. However, it also is possible to use as the second irradiance uniformizing member 9 a so-called glass rod (rod integrator) that functions as an internal reflection type integrator. This glass rod is an optical member formed in a rectangular prism (a square pillar) made of a transmissive material, such as glass, quartz glass, or crystal, that uniformizes the intensity distribution of the illumination light at the exit side by using internal reflection by side surfaces of the rod when the illumination light enters from one end and exits from the opposite end. Therefore, when the glass rod is used as the second irradiance uniformizing member 9, the exit surface (end) of the glass rod is positioned in a plane conjugate to the pattern surface of the reticle R.

In the projection exposure apparatus of this example, when the glass rod is used as the second irradiance uniformizing member 9, it is better to provide an aperture diaphragm having an opening in a shape similar to the one shown in FIG. 3A on the pupil plane in the illumination optical system that relays between the glass rod and the reticle R, for example. An aperture diaphragm having an opening in a shape similar to the one shown in FIG. 3A may be provided on or near the pupil plane with respect to the incident surface of the glass rod, between the exposure light source and the glass rod in the illumination optical system.

The incident angle range of the illumination light on the reticle R may be set in the predetermined range by positioning diffractive elements having a predetermined periodicity and direction near the incident surface of the glass rod or near the surface conjugate to the incident surface of the glass rod between the exposure light source and the glass rod in the illumination system. Alternatively, the incident angle range of the illumination light on the reticle can be configured at a predetermined range by providing a polyhedron prism or a cone prism at a location in the illumination optical system between the exposure light source and the glass rod. In addition, the diffractive elements or the prisms may be used combined with the aperture diaphragm.

When the incident angle range of the illumination light to the reticle is set without using the illumination aperture diaphragm, but with the above-described diffractive elements or prism, even if the fly eye lens or the glass rod is used as the second irradiance uniformizing member 9, the border of the angle range of the illumination light beam incident to the reticle R tends to be slightly blurred. In this case, the definitions of σx and σy that correspond to the incident angle range of the illumination light to the reticle, which are characteristics of this invention, are that σx is preferably a value of a sine of an angle of a half of the full width at half maximum (FWHM) of the distribution function of the illumination intensity distribution with respect to the incident angle of the illumination light to the reticle in the X direction, divided by a numerical aperture NAR of the projection optical system 23 on the reticle side, and σy is preferably a value of a sine of an angle of a half of the full width at half maximum (FWHM) of the distribution function of the illumination intensity distribution with respect to the incident angle of the illumination light to the reticle in the Y direction, divided by a numerical aperture NAR of the projection optical system 23 on the reticle side. Then, the effective σx and the effective σy should satisfy σx≧0.6 and 0≦σy<0.3, respectively. Of course, in this case as well, if σx≧0.6 and 0≦σy<0.3 are satisfied, the image forming performance with respect to a pattern having more micro pitches further improves.

Under the illumination conditions of this example, since the incident angle range of the illumination light in the X direction to the reticle patterns LC, LL1, LL2, LR1, LR2 and the like are increased at σx≧0.6 as shown in FIG. 5A, coherency (spatial coherency) of the illumination light irradiated to the reticle R in the X direction is significantly reduced compared to the conventional small σ illumination at σ between about 0.15 and about 0.3.

As a result, the variations of the transferred line width of the reticle patterns LC, LL1, LL2, LR1 and LR2 in accordance with the presence of other patterns existing in the X direction from these patterns become further reduced.

In addition, by a general relation between the resolution and σ value under the partial coherent illumination, the resolution in X direction also is improved with the increase of σx as described above in this invention compared to conventional small σ illumination at σ between about 0.15 and 0.3. Therefore, it becomes possible to increase the integration also in the X direction of pattern to be transferred by this invention.

The use of the illumination condition of this aspect of the invention has an effect of improving the uniformity of the line width in the X direction of the image transferred to the wafer with a pattern formed on the reticle that has a longitudinal direction extending in the X direction. Such an effect also can be obtained from the decreasing of coherency in the X direction of the illumination light irradiated on the reticle, which is achieved by this aspect of the invention.

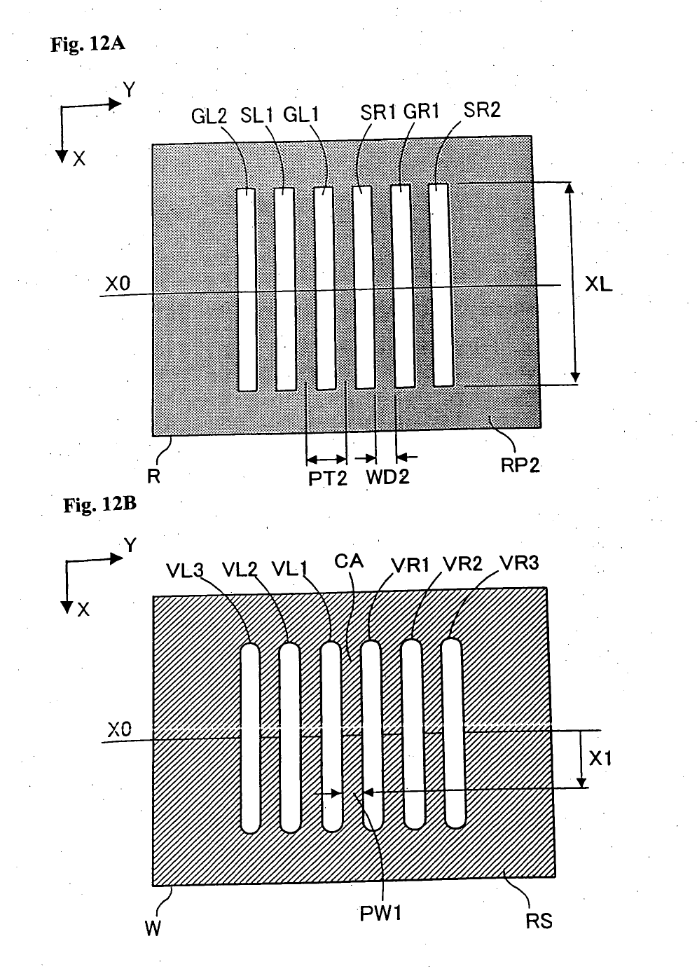

This effect is described with reference to FIGS. 12-15 below.

FIG. 12A is a diagram showing a shape of a reticle pattern used in the study of the simulation as described below. The reticle R is covered with an opaque film RP, such as chromium, and transmissive patterns GL2, SL1, GL1, SR1, GR1 and SR2 are formed therewith, having a longitudinal direction that coincides with the X direction. The transmissive patterns, GL2, SL1, GL1, SR1, GR1 and SR2 compose alternating phase shift patterns, as the phase of transmitted light from the transmissive patterns SL1, SR2 and SR2 are shifted by 180 degrees compared to the light transmitted from the rest of the transmissive patterns GL2, GL1 and GR1.

In each of the transmissive patterns GL2, SL1, GL1, SR1, GR1 and SR2, the line width in the Y direction is 150 nm, the pitch PT2 is 200 nm in the Y direction, and the length XL in the X direction is 1 μm (=1000 nm). Therefore, the line width WD2 of the opaque part formed between each of the transmissive patterns GL2, SL1, GL1, SR1, GR1 and SR2 becomes 50 nm as shown in the scale on the wafer W. This value is the same as the reticle pattern shown in FIG. 5A. These measurements are shown in the scale on the wafer W as the reduction magnification of the projection optical system 23 is considered compared to the value shown in the scale on the reticle R.

A line X0 indicates a center position of the transmissive patterns GL2, SL1, GL1, SR1, GR1 and SR2 in the X direction.

FIG. 12B is a drawing showing a resist pattern RS formed when the pattern in FIG. 12A is exposed and transferred onto the wafer W. The photoresist on the wafer W is assumed to use a positive type (in which a part that was exposed by the exposure dissolves by development). Because of this, parts VL3, VL2, VL1, VR1, VR2 and VR3 in which the resist is removed are formed on the wafer W, corresponding to the transmissive patterns GL2, SL1, GL1, SR1, GR1 and SR2 on the reticle R. Resist patterns are formed therebetween.

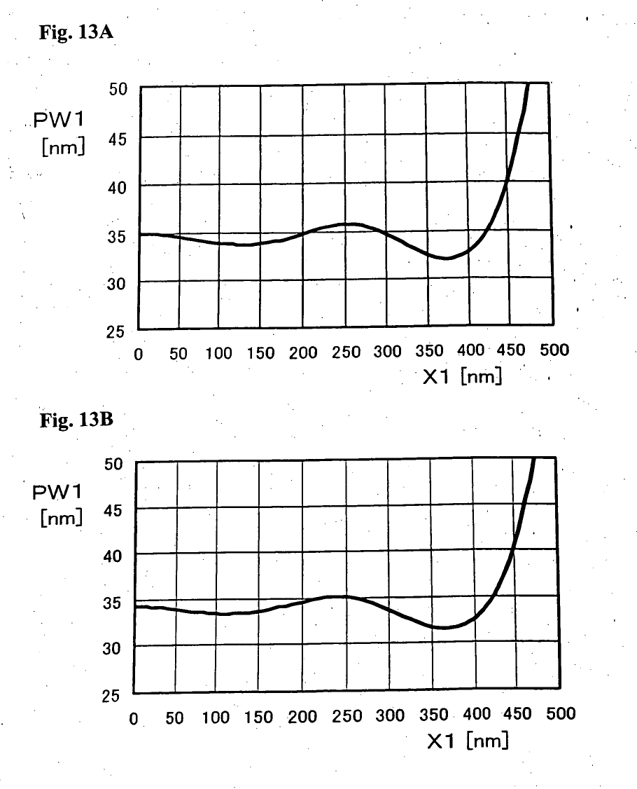

The relation between the line width PW1 versus X position calculated by optical simulations are shown in FIGS. 13-15. The relationship with a line width PW1 of a resist pattern CA placed at the center of Y direction and X position, that is a distance X1 from a center of X direction (X0) is shown in the figures.

FIGS. 13A and 13B are diagrams showing relationships between the line width PW1 of the resist pattern CA (vertical axis) and the position X1 in the X direction (horizontal axis) when a normal illumination at σ=0.15, which is a conventional exposure method, is used. Here, X1 being 0 corresponds to the center position X0 in the X direction. FIG. 13A shows results at the best focus position, and FIG. 13B shows results at the 50 nm-defocused position.

The calculation methods for other conditions of the optical simulation and the line width to be transferred are the same as the above-described optical simulation. A slice level SL was set such that the line width decided by the slice level SI at X1=0 becomes 35 nm at the best focus position.

In the small σ illumination at σ=0.15, the illumination light on the reticle R has high coherency in both the X and Y directions, therefore the intensity of an optical image to be transferred on the wafer changes depending on the position in the X direction on the reticle pattern, which is, more precisely, the position of an edge in the X direction on the reticle pattern (i.e., the position at X1=500, at which X1 becomes a half of the pattern length of 1000 nm). The line width to be transferred also changes greatly, accordingly. The changed width is about 4 nm in a range where X1 is between 0 and 400 nm. In addition, because the coherent length in the X direction on the reticle R is long, the line width of the transferred pattern significantly changes between 1 nm and 2 nm even at a position at X1=100, which is 400 nm away from the edge (X1=500).

As described above, if the line width of the transferred pattern changes along its longitudinal direction (here, X direction), when, for example, this pattern is a gate pattern of a MOS transistor, leak current (OFF-current) increases at a part where the line width narrows and ON-current decreases at a part where the line width is thick. Thus, the performance of the transistor formed by such irregular line width.

To prevent this, correcting a reticle pattern width WD2 itself based on an estimation of a line width change in the X direction, that is, the OPC is required. Such an OPC correction also increases the manufacturing cost of reticles.

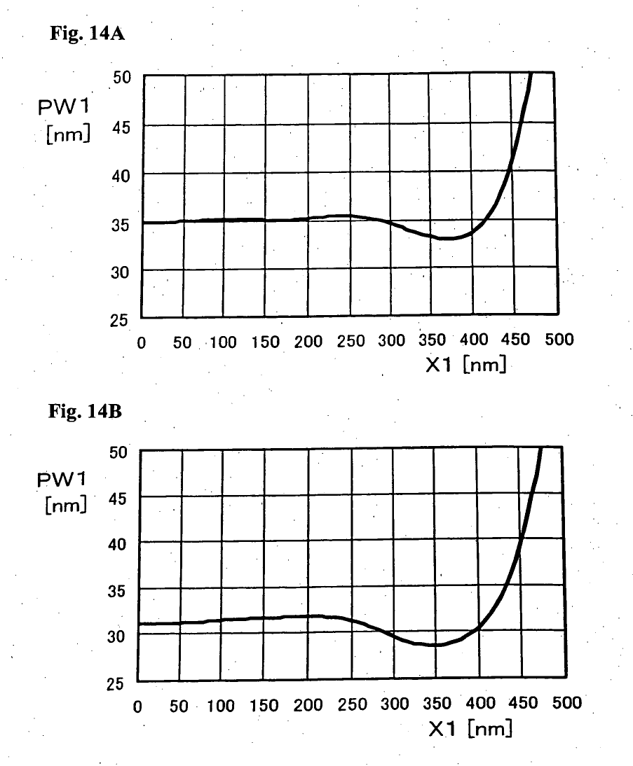

With respect to the simulation results when the conventional illumination at σ=0.30 is used, FIG. 14A shows results at the best focus position, and FIG. 14B shows results at the 50 nm-defocused position. Because the coherency of the illumination light on the reticle R decreases due to increase in the illumination σ value, the variations of the line width PW1 with respect to the change of the position X1 in the X direction decreases compared with the results shown in FIGS. 13A and 13B at both the best focus and defocus positions, and becomes about 2.5 nm in the range where X1 is between 0 and 400 nm. However, under a condition in which σy=0.30, a sufficient depth of focus cannot be obtained, and thus, it may be difficult to use the pattern with the resist line width of 35 nm for the exposure, as described above.

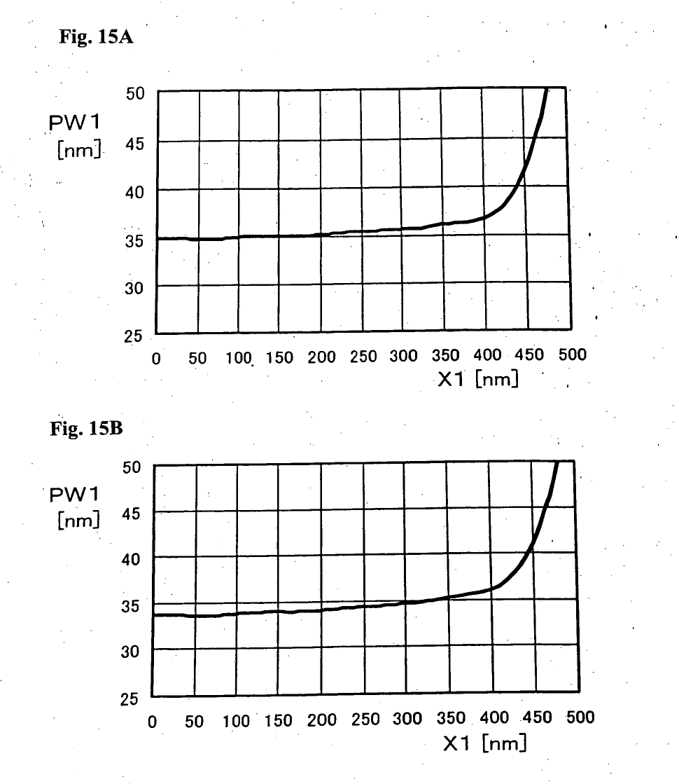

In contrast, simulation results of a case in which σx=0.85 and σ=0.15 are used as an example of the illumination conditions of some aspects of this invention are shown in FIGS. 15A-15B. FIG. 15A shows results at the best focus position, and FIG. 15B shows results at the 50 nm-defocus position. Under the illumination conditions according to some aspects of this invention, since the σ value (σx) of the illumination light in the X direction is equal to or more than 0.6, or more preferably equal to or more than 0.7, coherency in the X direction of the illumination light irradiated on the reticle R is low. As a result, the variations of the line width PW1 for the changes of the position X1 in the X direction is significantly reduced, and is about 2 nm in the range where X1 is between 0 and 400 nm.

Therefore, when a gate of a MOS transistor is exposed using the illumination condition of this aspect of the invention, the change in the line width of the transferred pattern for the changes in the position in the longitudinal direction (position in the X direction) of the gate becomes small, and thereby, it can contribute to improvements of the performance of the manufactured transistor. Though the change in transferred line width for the change in the position in the X direction also slightly remains under the illumination condition of the invention, the line width change can be corrected using a correction of the pattern on the reticle. Moreover, as clear from FIGS. 15A and 15B, the range in which the line width should be corrected in the OPC correction, should only be in a range from the edge to about 200 in the X direction of the reticle (range of X1 from 300 nm to 500 nm, which is 200 nm as a width). This is smaller compared to a range in which the correction is required when the conventional illumination at σ=0.15 is used (range of X1 from 100 nm to 500 nm, which is 400 nm as a width). Thus, the increase in the cost for manufacturing the reticle using the OPC correction can be minimized.

Furthermore, if the above-described change in the transferred line width that remains even with the use of the illumination conditions of aspects of this invention is an amount that can be ignored in view of the characteristics of the transistor, the OPC correction of the reticle is not necessary when the illumination condition of aspects of this invention is used. Therefore, in this case, an exposure method that has a high resolution and a sufficient depth of focus with respect to the pattern having any pitch without increasing at all the cost for manufacturing the reticles can be realized.

Next, the polarization control member 4 in the illumination optical system 50 in FIG. 1 is described.

As described above, when the pattern on the reticle R is a pattern such as a line pattern, which has a longitudinal direction in a predetermined direction, the image forming performance can be improved by making the illumination light to the reticle R linearly polarized light in which the polarization direction (direction of electric field) coincides with the longitudinal direction of the above-described pattern. The polarization control member 4 is an optical member for this purpose and controls the polarization condition of the illumination light irradiated on the reticle R.

When an excimer laser or a fluorine laser is used as an exposure light source 1, the light emitted from the light source is approximately linearly polarized. Thus, as the polarization control member 4, a member that converts (rotates) the direction of the linearly polarized light into the desired direction should be used. In other words, it can be achieved by configuring a half wave plate formed of an optical material, such as quartz (silicon dioxide crystal), magnesium fluoride or the like, that has birefringence and is rotatable about the optical axis AX1 of the illumination optical system 50 as the center of rotation. The polarization direction of the illumination illuminated on the reticle is controlled by the configuration of the rotational angle of this half wave plate.

On the other hand, when the exposure light source 1 generates an illumination beam other than the linearly polarized light, such as when the light source is a lamp or a random polarization laser, a polarization filter or a polarized beam splitter that transmits only a linearly polarized light in the predetermined direction is used as the polarization control member 4. However, the effects of this example can be obtained even if the illumination light to the reticle R is not made completely linearly polarized but if most of the intensity of the illumination light is made as predetermined linearly polarized light. Therefore, it is sufficient that the polarization selection ratio of the above-described polarization filter or polarized beam splitter be equal to or more than about 80%.

Even in the projection exposure apparatus of this embodiment, it may be preferable that the polarization condition of the illumination light illuminated on the reticle is non-polarized light depending on the exposure pattern. Therefore, it is preferable that the polarization control member 4 of the projection exposure apparatus of this embodiment is structured detachably or to be able to supply non-polarized illumination light. For example, when the exposure light source 1 is a laser beam source that generates almost linearly polarized illumination beam, the ejected illumination beam can be made linearly polarized or circularly polarized (i.e., substantially non-polarized) by using as the polarization control member 4 two quarter wave plates positioned in series along the optical axis AX1 and by rotating each of them separately about the optical axis AX1 as the rotational center.

For the exposure under the illumination condition of this embodiment, it is preferable that the longitudinal direction of the pattern on the reticle R to be exposed coincides with a predetermined direction (X direction in the above-described embodiment) as described above. When a plurality of patterns exist on the reticle R, it is preferable that the direction of each pattern, among the plurality of the patterns, in which the image forming performance is specially important (e.g., gate pattern of a transistor), is made uniform and that the longitudinal direction coincides with the predetermined direction.

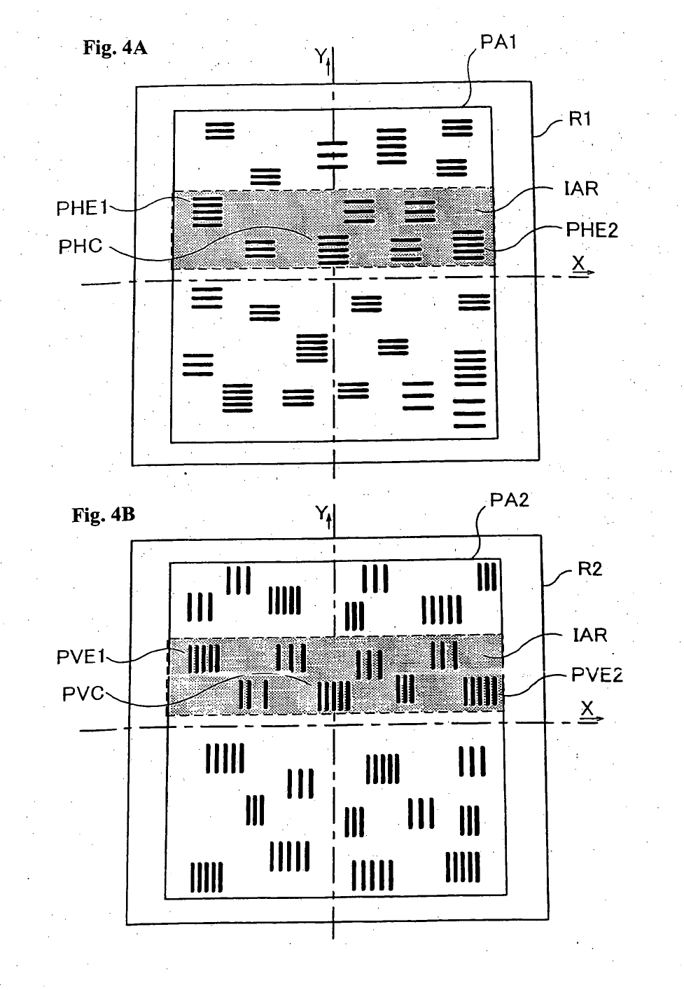

The details are described with reference to FIGS. 4A-4B below. FIGS. 4A and 4B are plan views, each showing an example of a reticle on which an original pattern that is appropriate for the exposure by the projection exposure apparatus of this embodiment is drawn.

FIG. 4A is a diagram showing a reticle R1 on which patterns PHC, PHE1, and PHE2, having longitudinal directions that are parallel with the X direction, are formed in a pattern area PA1. The reticle R1 includes other patterns; however, such other patterns are omitted since they are not as important for the image forming performance described herein.

Since the projection exposure apparatus of this embodiment is a scanning type exposure apparatus, having a scanning direction (scanning direction of the reticle R and the wafer W) that is in the Y direction, the exposure field (and illumination field of the projection exposure system 50) IAR of the projection optical system 23 in FIG. 1 is made a rectangle having a long side direction that coincides with the X direction non-scanning direction). Therefore, the longitudinal directions of the patterns PHC, PHE1 and PHE2 are parallel with the longitudinal direction of the exposure field IAR of the projection optical system 23 and orthogonal to the scanning direction. Since the reticle R1 is scanned in the Y direction with respect to the exposure field (illumination field), the other patterns existing in the pattern area PA1 but that are outside the exposure field IAR at the position shown also are exposed on the wafer W through the projection optical system.

In contrast, FIG. 4B is a diagram showing a reticle R2 on which patterns PVC, PVE1 and PVE2, having longitudinal directions that are parallel with the Y direction, are formed in a pattern area PA2. The reticle R2 includes other patterns; however, such other patterns are omitted since they are not as important for the image forming performance described herein. The patterns PVC, PVE1 and PVE2 on the reticle R2 differ from the patterns shown in FIG. 4A, in that the longitudinal directions are orthogonal to the longitudinal direction of the exposure field IAR of the projection optical system 23 and are parallel with the scanning direction.

In general, aberrations that deteriorate the image forming performance remain in the optical system. In the projection optical system for the projection exposure apparatus, although the remained aberrations are extremely small compared with optical systems for other purposes, it is unavoidable that some level of aberrations remain. In addition, the amount of aberrations remained generally increases in the periphery compared with the center of the exposure field of the projection optical system.

Such remaining aberrations include a component that blurs the transferred image in a radial direction from the optical axis to the periphery of the projection optical system (radial direction component) and a component that blurs the transferred image in the tangential direction about the optical axis of the projection optical system as the center (tangential direction component). However, in general, the radial direction component is larger. The component of the aberration of the radial direction component is coma aberrations and lateral chromatic aberrations. The correction of the coma aberrations is difficult from both points of view of design and manufacturing errors, and thus it is difficult to completely eliminate them.

The patterns PVE1 and PVE2 that are near the end parts of the exposure field IAR in the X direction and have the longitudinal directions extending in the Y direction as shown in FIG. 4B become patterns that are the most easily affected by the aberrations of the projection optical system. Therefore, in the transferred image of these patterns on the wafer W, there is a high risk of changes in the transferred line width and defects in resolution, as well as a high risk in lowering the production yield and deterioration of the performance of the produced LSI.

On the other hand, when the longitudinal direction of each pattern coincides with the long side direction (X direction) of the exposure field of the projection optical system 23 as shown in FIG. 4A, since the direction in which the blurring of the image due to the aberrations is large coincides with the longitudinal direction of the pattern in which high resolution performance are not required, the exposure with high resolution that is not substantially affected by the aberrations can become possible in the patterns PHE1 and PHE2 in the periphery of the exposure field IAR in the X direction.

Thus, in the projection exposure apparatus of this embodiment, it is preferable that the micro patterns on the reticle R to be exposed are positioned such that their longitudinal directions coincide with the long side direction (X direction) of the exposure field IAR of the projection optical system 23. That is, it is preferable that the incident angle range of the above-described illumination light that is appropriate for image forming of the reticle patterns is configured, premised on the fact that the micro patterns on the reticle R to be exposed are positioned such that their longitudinal direction coincides with the non-scanning direction (X direction) of the reticle.

In the above embodiment, a scanning type exposure apparatus was described. However, the exposure apparatus that can use the illumination condition of this invention is not limited to the scanning type. The illumination condition of this invention can be used for a stepper type (a type that exposes the reticle R and the wafer W while they are in a stationary state) exposure apparatus. In that case, since the exposure field of the projection optical system becomes a square or a rectangle in which a ratio of the long and short sides becomes close to 1:1, particularly desired relations are not generated between the longitudinal direction of the patterns placed on the reticle R and the shape of the exposure field, from a point of aberrations in the projection optical system. Therefore, the X and Y directions that were assumed when defining σx≧0.6, 0<σy≦0.3, and the like as described above as the illumination condition of this example do not have to have the predetermined relationship between an external form of the reticle or a total structure of the exposure tool.

Moreover, if the scanning type exposure apparatus has extremely small aberrations in the projection optical system, similar to the case of using the stepper type exposure apparatus, because particularly desired relationships are not generated between the longitudinal direction of the patterns placed on the reticle R and the exposure field of the projection optical system, the X and Y directions used when defining the illumination condition of the example do not have to be directions having particular predetermined relationships with respect to the entire exposure apparatus, scanning direction, and external shape of the reticle R.

In addition, the above-described exposure method is especially appropriate for the exposure of alternating phase shift reticles. In contrast, in the recent high-performance LSI, especially when exposing a gate layer, a double exposure may be used that exposes a part in the gate pattern that requires high resolution, with the alternating phase shift reticle, and another part, such as a wiring part, with a normal reticle (binary reticle).

The double exposure can be used with this invention. That is, for the wafer W to be exposed, the exposure using the illumination conditions of aspects of this invention is performed using the alternating phase shift reticle, and thereafter using a reticle switching mechanism not shown in the drawing, the reticle is replaced with a normal reticle to perform an overlay exposure to the same wafer W. At this time, for the exposure to the normal reticle, it is preferable to change the illumination condition to the so-called normal illumination, annular illumination, or dipole or quadrupole illumination. The order of double exposure is not limited as mentioned above. The exposure with a normal reticle can be executed before the exposure with an alternating phase shift reticle as the case may be.

In the projection exposure apparatus of the embodiment shown in FIG. 1, an optical path space from the exposure light source 1 to the wafer 1 may be filled with a gas, such as a chemically filtered air, an inert gas, such as nitrogen, or a rare gas. In particular, when an ArF excimer laser source or an F₂ laser source are used as the exposure light source 1, it is preferable to fill the optical path space for the illumination light with the inert gas or the rare gas.

Furthermore, the optical path space between the projection optical system 23 and the wafer W is not limited to a structure filled with a gas, such as air, nitrogen gas or rare gas (e.g., helium gas), but can be structured that the space is filled with liquid, such as water. In that case, since the wavelength of the illumination light irradiated onto the wafer W is reduced substantially by the refractive index of the liquid, the resolution of the projection optical system 23 improves.

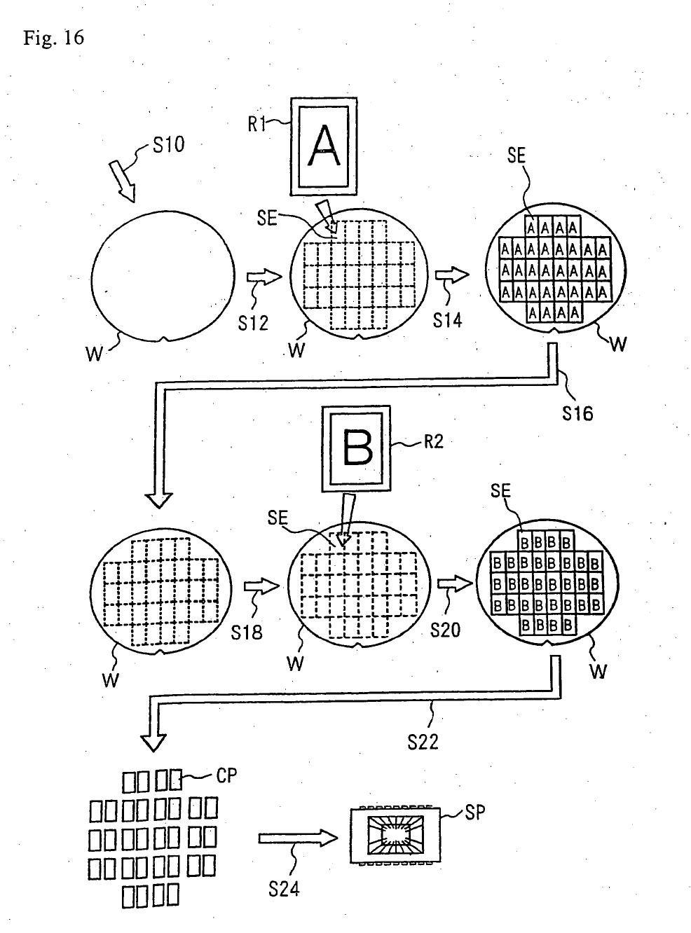

Next, an embodiment of a semiconductor device manufacturing process that uses the projection exposure apparatus of the above-described embodiment is described with reference to FIG. 16.

FIG. 16 shows an example of a semiconductor device manufacturing process. In FIG. 16, first a wafer W is produced from a silicon semiconductor or the like, and thereafter a photoresist is applied on the wafer (step S10). In the next step S12, a reticle (R1) on a reticle stage of the projection exposure apparatus of the above-described embodiment (FIG. 1) is loaded, and a pattern (represented by symbol A) on the reticle R1 is transferred (exposed) in the entire shot area SE on the wafer W by the scanning exposure method. At this time, a double exposure is performed if necessary. The wafer W may be a wafer having a diameter of 300 mm (12-inch wafer). An example of the size of the shot area SE may be a rectangular area having a width of 25 mm in the non-scanning direction and a width of 33 mm in the scanning direction. Next, in step S14, a predetermined pattern is formed in each of the shot areas SE on the wafer by development, etching or ion implantation.

Next, in step S16, the photoresist is applied on the wafer W. In step S18, a reticle (R2) on the reticle stage of the projection exposure apparatus of the above-described embodiment (FIG. 1) is loaded, and the pattern (represented by symbol B) on the reticle R2 is transferred (exposed) in each shot area SE on the wafer W by the scanning exposure method. In step S20, a desired pattern is formed in each shot area of the wafer by developing, etching and ion-implanting the wafer W.

The exposure process through the pattern forming process (step S16-step S20) may be repeated for the necessary number of times to manufacture the desired semiconductor device. Then, through a dicing process (step S22) that separates each chip CP on the wafer, a bonding process, and a packaging process (step 24) and the like, a semiconductor device SP is manufactured as a product.

According to the device manufacturing method of this embodiment, since at least one time of the exposure is conducted under the illumination condition of the above-described embodiment, costs of the reticle required for manufacturing semiconductor integrated circuits or costs for circuit designs can be reduced. In addition, semiconductor integrated circuits with a higher degree of integration than the conventional circuit can be manufactured with good yield. As a result of the above-described effects, according to the device manufacturing method of this embodiment, highly integrated and high-performance semiconductor integrated circuits can be produced at low costs.

The projection exposure apparatus of the above-described embodiment can be produced by installing and optically adjusting the illumination optical system and the projection optical system composed of a plurality of lenses in the exposure apparatus, mounting the reticle stage and the wafer stage made from a large number of mechanical parts on the exposure apparatus, connecting wires and pipes, and conducting the total adjustment (electric adjustment, operation test, etc.). This manufacturing of the exposure apparatus is preferably conducted in a clean room in which the temperature, degree of cleanness and the like are controlled.

The use of the exposure apparatus of this invention is not limited to the exposure apparatus for manufacturing semiconductor devices. However, it also can be widely used for the exposure apparatus for display devices, such as liquid crystal display elements formed on a rectangular glass plate, plasma displays and the like, as well as for exposure apparatus for manufacturing various devices, such as imaging elements (e.g., CCD), micromachines, thin film magnetic heads, and DNA chips. Furthermore, this invention can be applied to exposure processes (exposure apparatus) when manufacturing a mask (photomask, reticle, etc.) on which mask patterns of various devices are formed, using photolithographic processes.

Of course, this invention is not limited to the above-described embodiments, but may be formed by various structures without departing from the scope of this invention.

According to some aspects of this invention, the incident angle range of the illumination light or the effective σ value are configured in predetermined conditions different in two orthogonal directions.

In addition, according to some aspects of this invention, the OPE characteristics are improved and decreasing of DOF at a pattern having a predetermined pitch is prevented, when using alternating phase shift reticles.

Moreover, according to the device manufacturing method of some aspects of this invention, a high-performance device can be manufactured at low costs.

While the invention has been described with reference to preferred embodiments thereof, it is to be understood that the invention is not limited to the preferred embodiments or constructions. To the contrary, the invention is intended to cover various modifications and equivalent arrangements. In addition, while the various elements of the preferred embodiments are shown in various combinations and configurations, which are exemplary, other combinations and configurations, including more, less or only a single element, are also within the spirit and scope of the invention.

What is claimed is:

1. An exposure method for illuminating a pattern of a mask with illumination light to transfer an image of the pattern onto a substrate via a projection optical system, at least a part of the pattern on the mask has a longitudinal direction extending in a first direction, the method comprising:
setting a first incident angle range in the first direction of the illumination light illuminated onto the mask to be wider than a second incident angle range in a second direction orthogonal to the first direction of the illumination light illuminated onto the mask.

2. The exposure method according to claim 1, wherein the first incident angle range has an effective σ value for the first direction that is different from an effective σ value for the second incident angle range in the second direction.

3. The exposure method according to claim 2, wherein the effective σ value for the first direction is at least 0.6, and the effective σ value for the second direction is not more than 0.3 and more than 0.

4. The exposure method according to claim 3, wherein the effective σ value for the first direction is at least 0.7, and the effective σ value for the second direction is not more than 0.2.

5. The exposure method according to claim 1, wherein the at least a part of the mask pattern is an alternating type phase shift pattern having the longitudinal direction in the first direction.

6. The exposure method according to claim 1, wherein the first and second incident angle ranges of the illumination light to the mask are adjusted by an intensity distribution adjusting member.

7. The exposure method according to claim 6, wherein the intensity distribution adjusting member is an aperture diaphragm with a rectangular or oval opening positioned on or adjacent to a pupil plane of an illumination optical system that illuminates the mask with the illumination light.

8. The exposure method according to claim 1, wherein a polarization condition of a main component of the illumination light is set as a linearly polarized light in which a direction of its electric field coincides with the first direction.

9. The exposure method according to claim 7, wherein a polarization condition of a main component of the illumination light is set as a linearly polarized light in which a direction of its electric field coincides with a longitudinal direction of the opening in the aperture diaphragm.

10. The exposure method according to claim 1, wherein an intensity distribution with respect to the incident angle of the illumination light illuminated onto the mask in the first direction is higher at both ends of the incident angle range and lower in a middle of the incident angle range.

11. The exposure method according to claim 10, wherein the intensity distribution at the both ends of the incident angle range is 1.5 to 3 times as much as the intensity distribution at the middle of the incident angle range.

12. The exposure method according to claim 1, wherein the projection optical system has a rectangular exposure field having long sides extending in the first direction, and an illumination optical system has a rectangular illumination field having long sides extending in the first direction, and the mask and the substrate are exposed while being synchronously scanned in the second direction, while maintaining an image forming relationship between the mask and the substrate through the projection optical system.

13. An exposure method for illuminating a pattern of a mask with illumination light to transfer an image of the pattern onto a substrate via a projection optical system, wherein the substrate is exposed by multiple exposures using a first exposure method according to claim 1, and by a second exposure method different from the first exposure method.

14. An exposure apparatus comprising:
an illumination optical system that illuminates a mask with illumination light; and
a projection optical system that transfers an image of a pattern of the mask onto a substrate;
wherein a first incident angle range in the first direction of the illumination light illuminated onto the mask is wider than a second incident angle range in a second direction orthogonal to the first direction of the illumination light illuminated onto the mask.

15. The exposure apparatus according to claim 14, wherein the first incident angle range has an effective σ value for the first direction that is different from an effective σ value for the second incident angle range in the second direction.

16. The exposure apparatus according to claim 15, wherein the effective σ value for the first direction is at least 0.6, and the effective σ value for the second direction is not more than 0.3 and more than 0.

17. The exposure apparatus according to claim 16, wherein the effective σ value for the first direction is at least 0.7, and the effective σ value for the second direction is not more than 0.2.

18. The exposure apparatus according to claim 14, wherein at least a part of the pattern on the mask includes a pattern having a longitudinal direction in the first direction.

19. The exposure apparatus according to claim 14, further comprising an intensity distribution adjusting member that adjusts the first and second incident angle ranges of the illumination light illuminated onto the mask.

20. The exposure apparatus according to claim 19, wherein the intensity distribution adjusting member is an aperture diaphragm with a rectangular or oval opening positioned on or adjacent to a pupil plane of an illumination optical system that illuminates the mask with the illumination light.

21. The exposure apparatus according to claim 14, wherein the illumination optical system includes a polarization control member that makes a polarization condition of a main component of the illumination light as a linearly polarized light in which a direction of its electric field coincides with the first direction.

22. The exposure apparatus according to claim 20, wherein the illumination optical system includes a polarization control member that makes a polarization condition of a main component of the illumination light as a linearly polarized light in which a direction of its electric field coincides with a longitudinal direction of the opening in the aperture diaphragm.

23. The exposure apparatus according to claim 14, wherein an intensity distribution with respect to the incident angle of the illumination light illuminated onto the mask in the first direction is higher at both ends of the incident angle range and lower in a middle of the incident angle range.

24. The exposure apparatus according to claim 23, wherein the intensity distribution at the both ends of the incident angle range is 1.5 to 3 times as much as the intensity distribution at the middle of the incident angle range.

25. The exposure apparatus according to claim 14, wherein the illumination optical system includes a first illumination condition variable mechanism that varies the first and second incident angle ranges or intensity distribution of the illumination light distributed in the first and second incident angle ranges.

26. The exposure apparatus according to claim 25, wherein the illumination optical system includes a second illumination condition variable mechanism that, as an alternative to the first illumination condition variable mechanism, makes the incident angle ranges of the illumination light to be outside of the first and second incident angle ranges.

27. The exposure apparatus according to claim 26, wherein the illumination condition that the second illumination condition variable mechanism sets includes annular illumination, dipole illumination and quadrupole illumination.

28. The exposure apparatus according to claim 14, wherein an exposure field of the projection optical system has a rectangular shape having long sides extending in the first direction, and an illumination field of the illumination optical system has a rectangular shape having long sides extending in the first direction, the exposure apparatus further comprising a stage mechanism that synchronously scans the mask and the substrate while maintaining an image forming relationship between the mask and the substrate through the projection optical system, a direction of the synchronous scanning coincides with the second direction.

29. A device manufacturing method including a process that transfers a device pattern onto a substrate by using the exposure method according to claim 1.
